(19) United States
(12) Patent Application Publication
(10) Pub. No.: US 2025/0248085 A1
(43) Pub. Date: Jul. 31, 2025

(54) SEMICONDUCTOR DEVICE

(71) Applicant: Samsung Electronics Co., Ltd., Suwon-si (KR)

(72) Inventors: KYEN-HEE LEE, Suwon-si (KR); JINMYOUNG LEE, Suwon-si (KR)

(21) Appl. No.: 18/816,710

(22) Filed: Aug. 27, 2024

(30) Foreign Application Priority Data
Jan. 30, 2024 (KR) 10-2024-0014147

(51) Int. Cl. H01L 29/06; H01L 29/423; H01L 29/775; H01L 29/786

(52) U.S. Cl. CPC H10D 62/121; H10D 30/43; H10D 30/6735; H10D 30/6756; H10D 30/6757

(57) ABSTRACT

A semiconductor device may include a substrate including an active pattern, a fin pattern on the active pattern, a first channel supporting pattern on a bottom surface of the fin pattern and a second channel supporting pattern on a top surface of the fin pattern, a channel pattern on each of the first and second channel supporting patterns, a gate electrode on the channel pattern, a channel seed pattern provided on a side portion of the channel pattern, and an isolation wall pattern on a side surface of the channel seed pattern and a side surface of the fin pattern. The channel pattern may extend from a region on the first channel supporting pattern to a region on the second channel supporting pattern via a side surface of the fin pattern.

### CROSS-REFERENCE TO RELATED APPLICATIONS

This U.S. non-provisional patent application claims priority under 35 U.S.C. § 119 to Korean Patent Application No. 10-2024-0014147, filed on Jan. 30, 2024, in the Korean Intellectual Property Office, the entire contents of which are hereby incorporated by reference.

### BACKGROUND OF THE INVENTION

The present disclosure relates to a semiconductor device, and in particular, to a semiconductor device including a field effect transistor.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical challenges associated with the scale-down of the semiconductor device and to realize high-performance semiconductor devices.

### SUMMARY

An embodiment of the inventive concept provides a semiconductor device with an increased integration density.

An embodiment of the inventive concept provides a semiconductor device with improved reliability.

According to an embodiment of the inventive concept, a semiconductor device may include a substrate including an active pattern, a fin pattern on the active pattern, a first channel supporting pattern on a bottom surface of the fin pattern and a second channel supporting pattern on a top surface of the fin pattern, a channel pattern on each of the first and second channel supporting patterns, a gate electrode on the channel pattern, a channel seed pattern provided on a side portion of the channel pattern, and an isolation wall pattern on a side surface of the channel seed pattern and a side surface of the fin pattern. The channel pattern may extend from a region on the first channel supporting pattern to a region on the second channel supporting pattern via a side surface of the fin pattern.

According to an embodiment of the inventive concept, a semiconductor device may include a substrate including an active pattern, a fin pattern on the active pattern, channel supporting patterns on each of bottom and top surfaces of the fin pattern, a channel pattern on the channel supporting patterns, a gate electrode on the channel pattern, a gate insulating layer interposed between the gate electrode and the channel pattern, a channel seed pattern provided on a side portion of the channel pattern, and an isolation wall pattern on a side surface of the channel seed pattern and a side surface of the fin pattern. The channel seed pattern may include transition metal oxide, and the channel pattern may include two-dimensional transition metal chalcogenide.

According to an embodiment of the inventive concept, a semiconductor device may include a substrate including a first active pattern and a second active pattern, a device isolation layer defining the first and second active patterns, first fin patterns on the first active patterns, second fin patterns on the second active patterns, first channel supporting patterns on the first fin patterns and on the first active pattern, second channel supporting patterns on the second fin patterns and on the second active pattern, first two-dimensional semiconductor compound patterns on the first channel supporting patterns vertically spaced apart from each other, second two-dimensional semiconductor compound patterns on the second channel supporting patterns vertically spaced apart from each other, a first source/drain pattern connected to the first two-dimensional semiconductor compound patterns, and a second source/drain pattern connected to the second two-dimensional semiconductor compound patterns. The semiconductor device may further include a first gate electrode on first two-dimensional semiconductor compound patterns, portions of the first gate electrode being interposed between adjacent ones of the first two-dimensional semiconductor compound patterns. The semiconductor device may further include a second gate electrode on second two-dimensional semiconductor compound patterns, portions of the second gate electrode being interposed between adjacent ones of the second two-dimensional semiconductor compound patterns. The semiconductor device may further include an isolation wall pattern on the device isolation layer, the isolation wall pattern comprising a body portion on the device isolation layer and protruding portions protruding from the body portion, first channel seed patterns interposed between the protruding portions and the first two-dimensional semiconductor compound patterns, second channel seed patterns interposed between the protruding portions and the second two-dimensional semiconductor compound patterns, a gate insulating layer interposed between the gate electrode and each of the first and second two-dimensional semiconductor compound patterns, a gate capping pattern on a top surface of the gate electrode, an interlayer insulating layer covering the first and second source/drain patterns and the gate capping pattern, a gate contact provided to penetrate the gate capping pattern and the interlayer insulating layer and electrically connected to the gate electrode, a first interconnection line electrically connected to the gate contact, and a second interconnection line electrically connected to the first metal layer. A first side surface of each of the first and second channel seed patterns is in contact with the protruding portion. A second side surface of each of the first and second channel seed patterns is in contact with the first and second channel patterns.

### BRIEF DESCRIPTION OF THE DRAWINGS

FIGS. 1 to 3 are conceptual diagrams illustrating logic cells of a semiconductor device according to an embodiment of the inventive concept.

FIG. 4 is a plan view illustrating a semiconductor device according to an embodiment of the inventive concept.

FIGS. 5A to 5E are sectional views taken along lines A-A′, B-B′, C-C′, D-D′, and E-E′, respectively, of FIG. 4.

FIG. 6A is an enlarged sectional view illustrating a portion ‘M’ of FIG. 5A, and FIG. 6B is an enlarged sectional view illustrating a portion ‘N’ of FIG. 5E, and FIG. 6C is an enlarged sectional view illustrating a portion ‘NN’ of FIG. 6B.

FIGS. 7A to 16D are sectional views illustrating a method of fabricating a semiconductor device according to an embodiment of the inventive concept.

### DETAILED DESCRIPTION

Example embodiments of the inventive concepts will now be described more fully with reference to the accompanying drawings, in which example embodiments are shown.

It should be noted that items described in the singular herein, may be provided in plural, as can be seen in the various figures from the context in which they are described.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” or “having” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

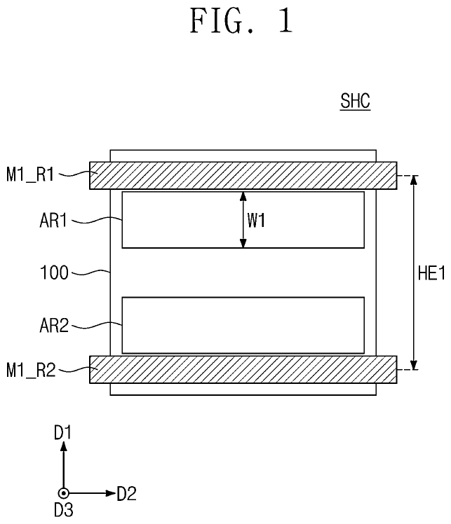

FIGS. 1 to 3 are conceptual diagrams illustrating logic cells of a semiconductor device according to an embodiment of the inventive concept.

Referring to FIG. 1, a single height cell SHC may be provided. In standard cell layout for integrated circuit design, a row may refer to a horizontal strip of the layout where standard cells are placed. Each row is a region where cells are aligned side by side to create the circuit. The single height cell SHC may be a cell that fits within a single row of a standard cell layout in a plan view. In detail, a first power line M1_R1 and a second power line M1_R2 may be provided on a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET (p-type metal oxide semiconductor field effect transistor) region, and the other may be an NMOSFET (n-type metal oxide semiconductor field effect transistor) region. For example, the single height cell SHC may have a CMOS structure provided between the first and second power lines M1_R1 and M1_R2.

Each of the first and second active regions AR1 and AR2 may have an active width W1 in a first direction D1. A length of the single height cell SHC in the first direction D1 may be defined as a single height cell height HE1. The single height cell height HE1 may be substantially equal to a distance (e.g., a pitch) between the first power line M1_R1 and the second power line M1_R2.

The single height cell SHC may constitute a single logic cell. In the present specification, the logic cell may mean a logic device (e.g., AND, OR, XOR, XNOR, inverter, and so forth), which is configured to execute a specific function. For example, the logic cell may include transistors constituting the logic device and interconnection lines connecting the transistors to each other.

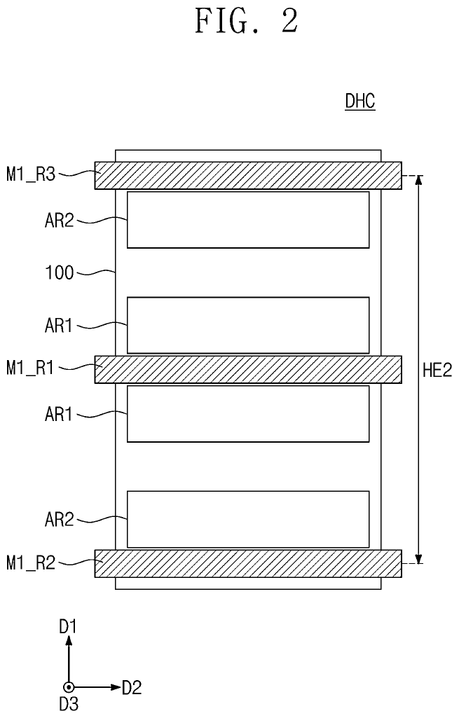

Referring to FIG. 2, a double height cell DHC may be provided. The double height cell DHC may be a cell that fits within a double row of a standard cell layout in a plan view. In detail, the first power line M1_R1, the second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the source voltage VSS is provided.

The double height cell DHC may be defined between the second power line M1_R2 and the third power line M1_R3. The double height cell DHC may include two first active regions AR1 and two second active regions AR2.

One of the second active regions AR2 may be adjacent to the second power line M1_R2. The other of the second active regions AR2 may be adjacent to the third power line M1_R3. The two first active regions AR1 may be adjacent to the first power line M1_R1. When viewed in a plan view, the first power line M1_R1 may be disposed between the two first active regions AR1.

A length of the double height cell DHC in the first direction D1 may be defined as a double height cell height HE2. The double height cell height HE2 may be about two times the single height cell height HE1 of FIG. 1. The first active regions AR1 of the double height cell DHC may be combined to serve as a single active region.

In an embodiment, the double height cell DHC shown in FIG. 2 may be defined as a multi-height cell. Although not shown, the multi-height cell may include a triple height cell whose cell height is about three times that of the single height cell SHC.

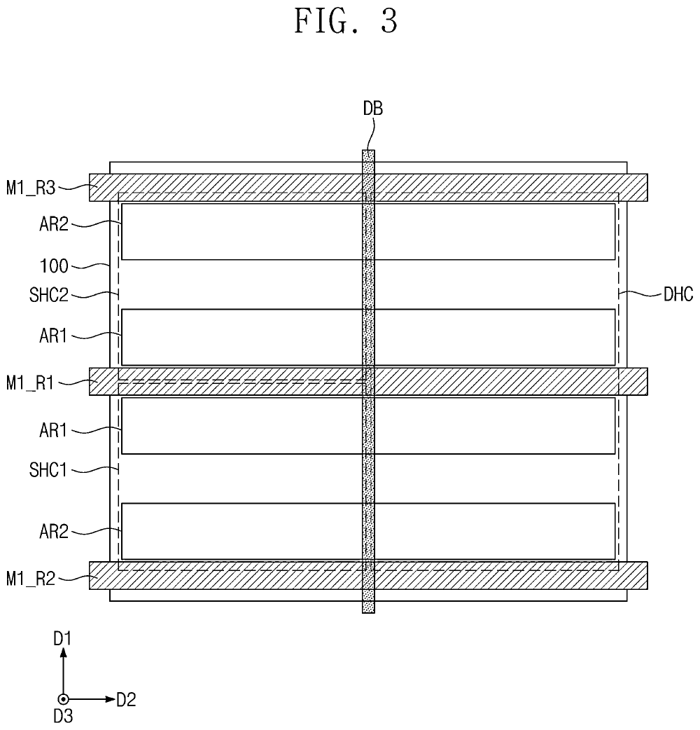

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. An active region of the double height cell DHC may be electrically separated from an active region of each of the first and second single height cells SHC1 and SHC2 by the division structure DB.

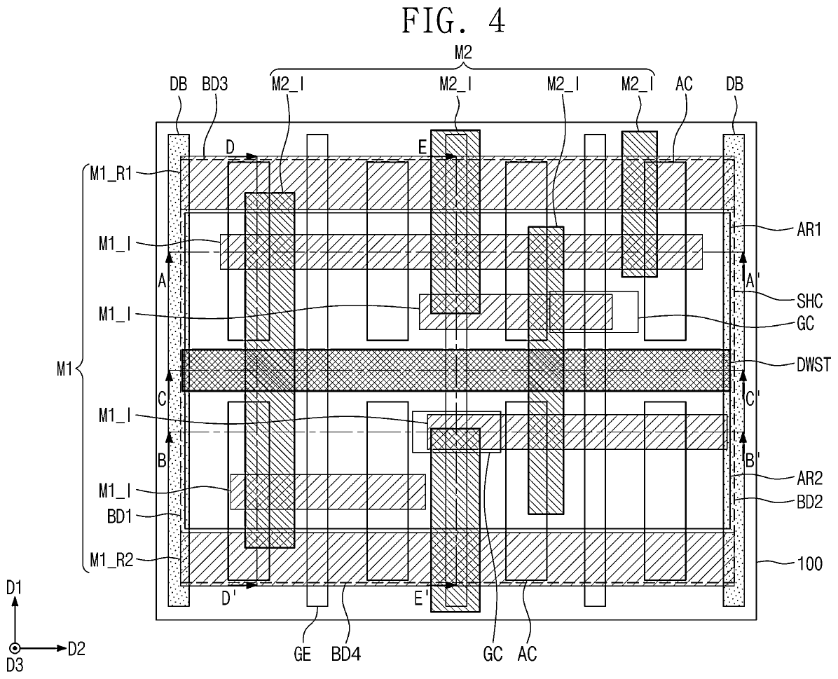

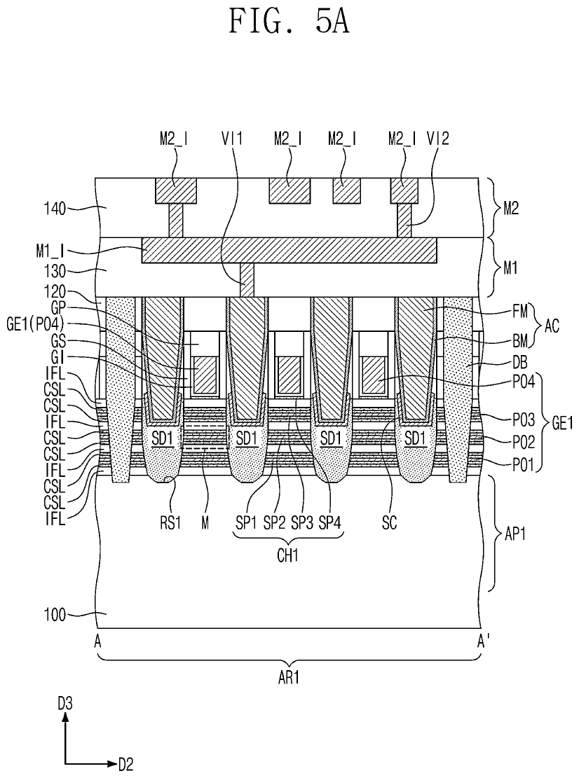

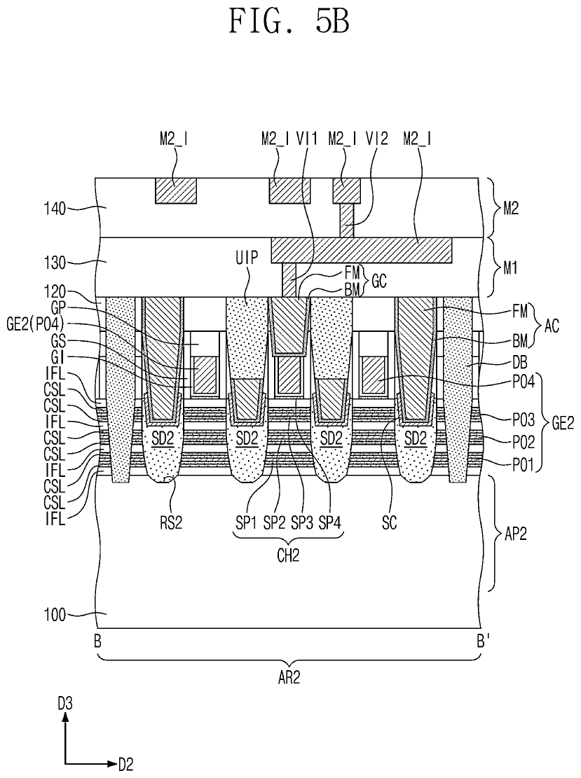

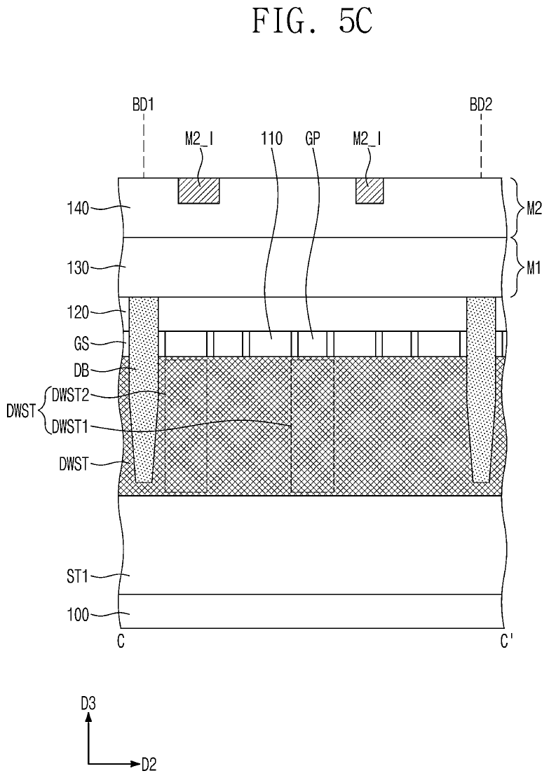

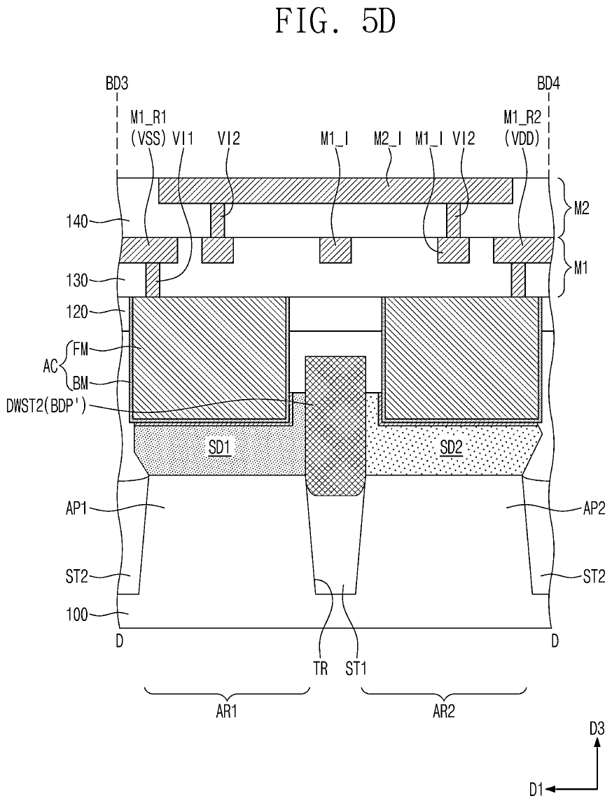

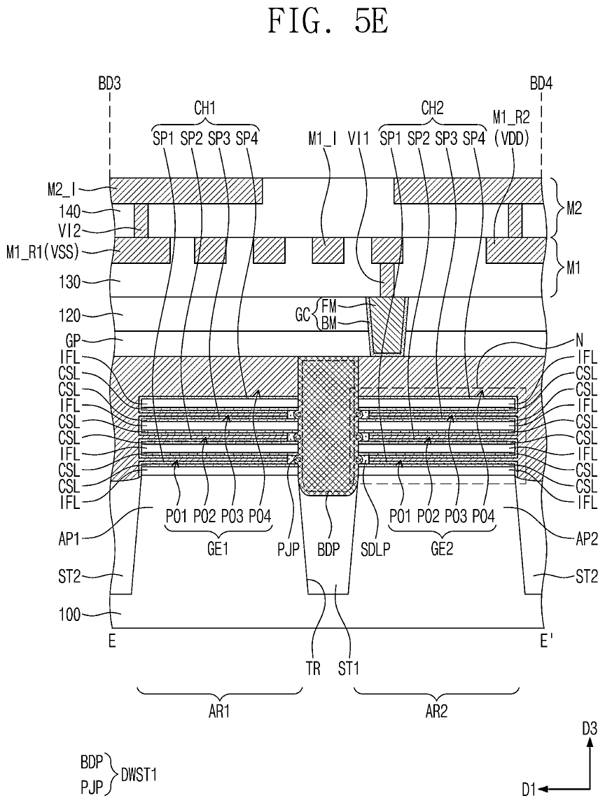

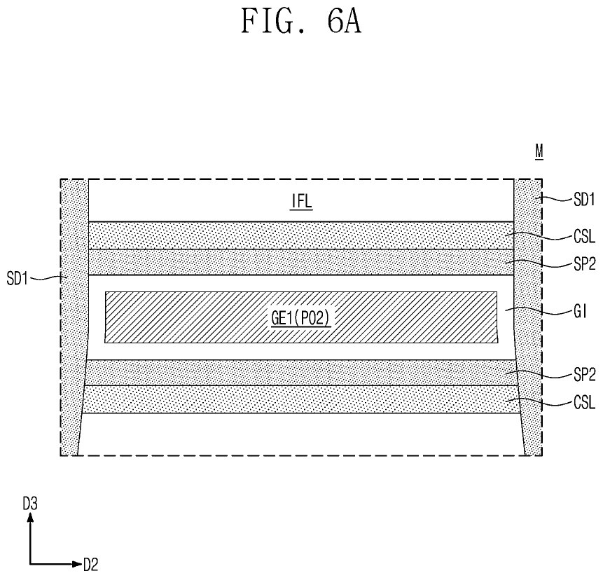

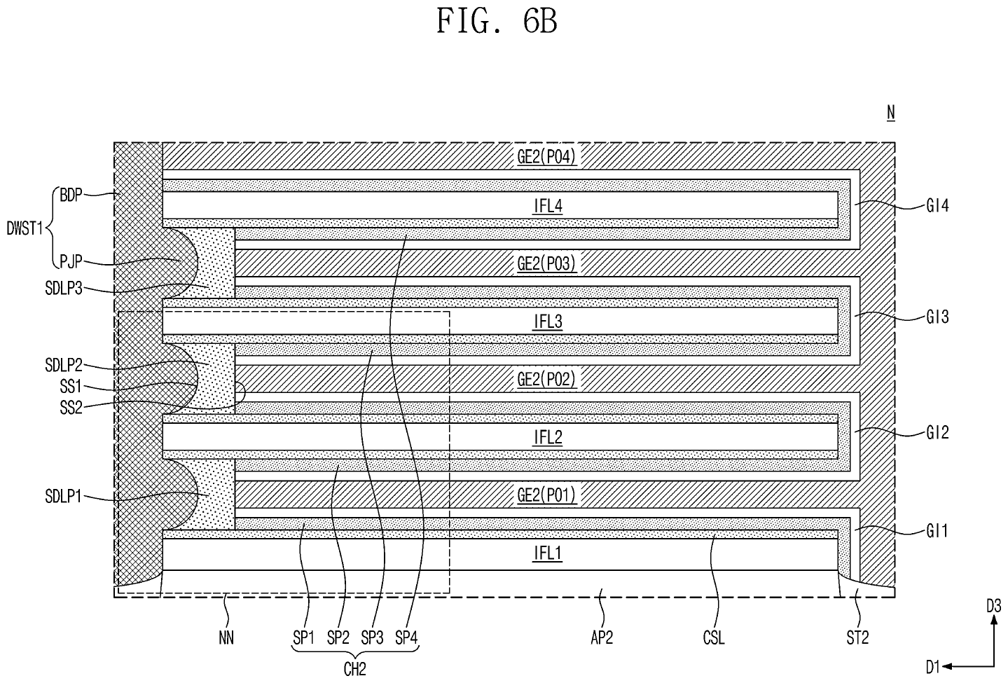

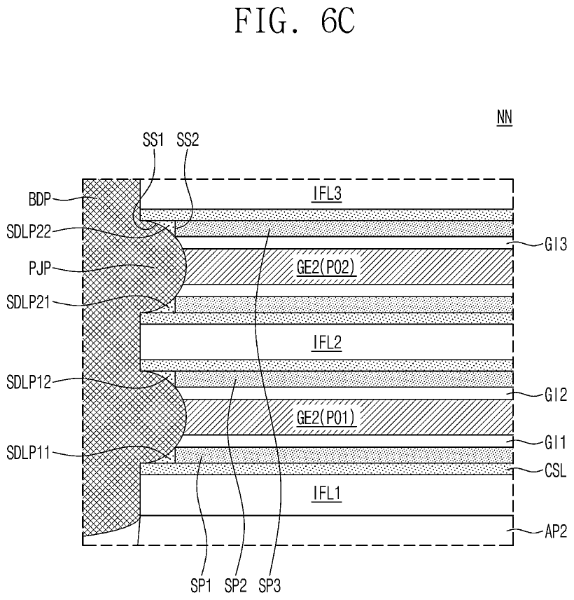

FIG. 4 is a plan view illustrating a semiconductor device according to an embodiment of the inventive concept. FIGS. 5A to 5E are sectional views taken along lines A-A′, B-B′, C-C′, D-D′, and E-E′, respectively, of FIG. 4. FIG. 6A is an enlarged sectional view illustrating a portion ‘M’ of FIG. 5A, and FIG. 6B is an enlarged sectional view illustrating a portion ‘N’ of FIG. 5E. The semiconductor device of FIGS. 4 and 5A to 5E may be a concrete example of the single height cell SHC of FIG. 1.

Referring to FIG. 4 and FIGS. 5A to 5E, a single height cell SHC may be provided on the substrate 100. Logic transistors constituting a logic circuit may be disposed on (or in) the single height cell SHC. The substrate 100 may be a semiconductor substrate that is formed of or includes silicon, germanium, silicon germanium, a compound semiconductor material, or the like. As an example, the substrate 100 may be a silicon substrate. In an embodiment, the substrate 100 may include a silicon-based insulating layer. For example, the substrate 100 may be an insulating substrate. The insulating substrate may include a silicon oxide layer, a silicon nitride layer, or a silicon oxynitride layer.

The substrate 100 may include the first active region AR1 and the second active region AR2. Each of the first and second active regions AR1 and AR2 may extend in the second direction D2. In an embodiment, the first active region AR1 may be an NMOSFET region, and the second active region AR2 may be a PMOSFET region.

A first active pattern AP1 and a second active pattern AP2 may be defined by a trench TR, which is formed in an upper portion of the substrate 100. The first active pattern AP1 may be provided on the first active region AR1, and the second active pattern AP2 may be provided on the second active region AR2. The first and second active patterns AP1 and AP2 may extend in the second direction D2. Each of the first and second active patterns AP1 and AP2 may be a vertically protruding portion of the substrate 100.

Device isolation layers ST1 and ST2 may be provided on the substrate 100. The first and second active patterns AP1 and AP2 may be defined by the device isolation layers ST1 and ST2. The device isolation layers ST1 and ST2 may fill the trench TR. In detail, a first device isolation layer ST1 may fill the trench TR between the first and second active patterns AP1 and AP2. A second device isolation layer ST2 may be provided to fill the trench TR between the first active patterns AP1 or the trench TR between the second active patterns AP2. For example, the second device isolation layer ST2 may be provided to fill the trench TR between the first active pattern AP1 (or the second active pattern AP2) in the single height cell SHC and another first active pattern AP1 (or the second active pattern AP2) in an adjacent single height cell (though not shown in the drawings). The device isolation layers ST1 and ST2 may include a silicon oxide layer. The device isolation layers ST1 and ST2 may not cover first and second channel patterns CH1 and CH2, which will be described below.

Fin patterns IFL may be provided on the first and second active patterns AP1 and AP2, respectively. The fin patterns IFL may be base patterns that are used to support a channel supporting pattern CLS and the channel patterns CH1 or CH2 to be described below. For example, the fin patterns IFL may be provided to support fork-sheets as described below. The fin patterns IFL may include at least one of silicon oxide, silicon nitride, and silicon oxynitride. In an embodiment, the fin patterns IFL may be formed of or include silicon oxide (SiO₂).

In detail, the fin patterns IFL may include a first fin pattern IFL1, a second fin pattern IFL2, a third fin pattern IFL3, and a fourth fin pattern IFL4. The first to fourth fin patterns IFL1 to IFLA may be sequentially stacked and may be spaced apart from each other in a vertical direction (i.e., a third direction D3). Although not shown, more than four fin patterns IFL may be provided, and the number of the fin patterns IFL may be variously changed depending on the required characteristics of the semiconductor device.

A channel supporting pattern CSL may be provided on each of the fin patterns IFL. In detail, the channel supporting pattern CSL may be provided on top and bottom surfaces of the fin pattern IFL. The channel supporting pattern CSL may be a base pattern supporting the channel patterns CH1 or CH2. The channel supporting pattern CSL may be formed of or include hafnium oxide. The channel supporting pattern CSL may have an amorphous structure.

In detail, the channel supporting pattern CSL may be provided on a top surface of the first fin pattern IFL1. The channel supporting pattern CSL may be provided on bottom and top surfaces of each of the second and third fin patterns IFL2 and IFL3. The channel supporting pattern CLS may be provided on a bottom surface of the fourth fin pattern IFL4.

A plurality of first channel patterns CH1 may be provided on the first active pattern AP1. A plurality of second channel patterns CH2 may be provided on the second active pattern AP2. For example, the first and second channel patterns CH1 and CH2 may be provided on the channel supporting pattern CSL. Each of the first and second channel patterns CH1 and CH2 may include a first two-dimensional semiconductor compound pattern SP1, a second two-dimensional semiconductor compound pattern SP2, a third two-dimensional semiconductor compound pattern SP3, and a fourth two-dimensional semiconductor compound pattern SP4. The first to fourth two-dimensional semiconductor compound patterns SP1, SP2, SP3, and SP4 may be sequentially stacked and may be spaced apart from each other in a vertical direction (i.e., the third direction D3).

The first to fourth two-dimensional semiconductor compound patterns SP1, SP2, SP3, and SP4 may be formed of a two-dimensional material. The two-dimensional material may be formed as a sheet having a nanoscopic thickness. The two-dimensional material may be one or two atoms (or molecules) thick. The material may have crystal structure. The two-dimensional material may exhibit unique electrical, mechanical, and optical properties due to their reduced dimensionality.

In an embodiment of the invention, though not shown in the drawings, the first to fourth two-dimensional semiconductor compound patterns SP1, SP2, SP3, and SP4 may be integrally formed. For example, the first to fourth two-dimensional semiconductor compound patterns SP1, SP2, SP3, and SP4 may be formed connected together. Each of which are a part of a two-dimensional semiconductor compound pattern CH1 (or CH2) formed integrally. In this case, the two-dimensional semiconductor compound pattern CH1 (or CH2) may interpose between the channel seed pattern SDLP and a gate electrode GE (described later).

Each of the first to fourth two-dimensional semiconductor compound patterns SP1, SP2, SP3, and SP4 may include two-dimensional transition metal chalcogenide. For example, the first to fourth two-dimensional semiconductor compound patterns SP1, SP2, SP3, and SP4 may include at least one of MoS2, WS2, MoSe2, WSe2, MoTe2, and WTe2. In embodiments of the invention, the material of the first to fourth two-dimensional semiconductor compound patterns may be crystalline, such as in the form of a single-crystalline structure.

In an embodiment, the first to fourth two-dimensional semiconductor compound patterns SP1, SP2, SP3, and SP4 may be formed of or include WSe2. In an embodiment, the first to fourth two-dimensional semiconductor compound patterns SP1, SP2, SP3, and SP4 may be fork-sheets that are stacked. The term fork-sheet may refer to the channel patterns CH1 and CH2 having a forked or split design of the channel patterns.

Channel seed patterns SDLP may be provided between each of the first and second channel patterns CH1 and CH2 and a backbone structure DWST (also referred as an isolation wall pattern) to be described below. The channel seed patterns SDLP may be provided on respective side portions of the first and second channel patterns CH1 and CH2. The channel seed patterns SDLP may be sequentially stacked and may be spaced apart from each other in a vertical direction (i.e., the third direction D3). The channel seed patterns SDLP may include a transition metal oxide material. For example, the channel seed patterns SDLP may be formed of or include at least one of WOx and MoOx.

In detail, the channel seed patterns SDLP may include a first channel seed pattern SDLP1, a second channel seed pattern SDLP2, and a third channel seed pattern SDLP3. The total number of the channel seed patterns SDLP may be three. Although not shown, the total number of the channel seed patterns SDLP may be greater than or equal to three and may be variously changed depending on the characteristics of the semiconductor device. The total number of the channel seed patterns SDLP may be smaller than the total number of the fin patterns IFL. Hereinafter, the channel patterns CH1 and CH2 and the channel seed pattern SDLP will be described in more detail with reference to FIG. 6B.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The plurality of first channel patterns CH1 may be interposed between two adjacent the first source/drain patterns SD1. For example, the first source/drain patterns SD1 in each pair may be connected to each other by the stacked first to fourth two-dimensional semiconductor compound patterns SP1, SP2, SP3 and SP4.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). The plurality of second channel patterns CH2 may be interposed between two adjacent the second source/drain patterns SD2. For example, the second source/drain patterns SD2 of each pair may be connected to each other by the stacked first to fourth two-dimensional semiconductor compound patterns SP1, SP2, SP3 and SP4.

The first and second source/drain patterns SD1 and SD2 may be epitaxial patterns, which are formed by a selective epitaxial growth (SEG) process. In an embodiment, a top surface of each of the first and second source/drain patterns SD1 and SD2 may be higher than a top surface of the third two-dimensional semiconductor compound pattern SP3. Alternatively, the top surface of each of the first and second source/drain patterns SD1 and SD2 may be located at substantially the same level as a top surface of the fourth fin pattern IFL4. In an embodiment, a top surface of at least one of the first and second source/drain patterns SD1 and SD2 may be located at substantially the same level as the top surface of the third two-dimensional semiconductor compound pattern SP3.

In an embodiment, the first source/drain pattern SD1 may be formed of or include the same semiconductor material (e.g., Si) as the substrate 100. The second source/drain patterns SD2 may include a semiconductor material (e.g., SiGe) which has a lattice constant larger than that of the semiconductor material (e.g., Si) of the substrate 100 or the first source/drain pattern SD1. In this case, the second source/drain patterns SD2 may exert a compressive stress on the plurality of second channel patterns CH2, which are located between the second source/drain patterns SD2.

In an embodiment, each of the second source/drain patterns SD2 may include a buffer layer and a main layer on the buffer layer. A volume of the main layer may be larger than a volume of the buffer layer. Each of the buffer and main layers may be formed of or include silicon-germanium (SiGe). In detail, the buffer layer may contain germanium (Ge) of a relatively low concentration. In another embodiment, the buffer layer may be formed of or include only silicon (Si), without germanium (Ge). The germanium concentration of the buffer layer may be in a range from 0 at % (atomic percent) to 30 at %.

The main layer may contain germanium (Ge) of a relatively high concentration. In an embodiment, the germanium concentration of the main layer may be in a range from 30 at % to 70 at %. The germanium concentration of the main layer may increase as a height in the third direction D3 increases. The germanium concentration within the main layer may vary along the third direction D3 to have a concentration gradient. For example, the germanium concentration may gradually increase from the lower to the upper direction. For example, the main layer adjacent to the buffer layer may have a germanium concentration of about 40 at %, and an upper portion of the main layer may have a germanium concentration of about 60 at %.

Each of the buffer and main layers may contain an impurity (e.g., boron, gallium, or indium) that allows the second source/drain pattern SD2 to have a p-type conductivity. The impurity concentration of each of the buffer and main layers may be in a range from 1E18 (E notation, or one times ten to the eighteenth power) atom/cm3 to 5E22 atom/cm3. The impurity concentration of the main layer may be higher than the impurity concentration of the buffer layer.

The buffer layer may be used to protect the main layer in a manufacturing process step, which will be described later. For example, during a replacing sacrificial layers SAL with first to third electrodes PO1, PO2, and PO3 of a gate electrode GE, the buffer layer may prevent an etchant material, which is used to remove the sacrificial layers SAL, from entering and etching the main layer.

Each of the first source/drain patterns SD1 may be formed of or include silicon (Si). The first source/drain pattern SD1 may further include impurities (e.g., phosphorus, arsenic, or antimony) that allow the first source/drain pattern SD1 to have a n-type conductivity. The impurity concentration of the first source/drain pattern SD1 may be in a range from 1E18 atom/cm3 to 5E22 atom/cm3.

In an embodiment, the second source/drain pattern SD2 may have an uneven or embossing side surface. For example, the side surface of the second source/drain pattern SD2 may have a wavy profile. The side surface of the second source/drain pattern SD2 may protrude toward the first to third electrodes PO1, PO2, and PO3 of the gate electrode GE.

First and second gate electrodes GE1 and GE2 may be provided on the first and second channel patterns CH1 and CH2. The first and second gate electrodes GE1 and GE2 may extend in the first direction D1 to cross the first and second channel patterns CH1 and CH2. Each of the first and second gate electrodes GEL and GE2 may be vertically overlapped with a corresponding one of the first and second channel patterns CH1 and CH2. The first and second gate electrodes GE1 and GE2 may be arranged at a first pitch in the second direction D2.

Each of the first and second gate electrodes GE1 and GE2 may include a first electrode PO1 interposed between the first two-dimensional semiconductor compound pattern SP1 and the second two-dimensional semiconductor compound pattern SP2, a second electrode PO2 interposed between the second two-dimensional semiconductor compound pattern SP2 and the third two-dimensional semiconductor compound pattern SP3, a third electrode PO3 interposed between the third two-dimensional semiconductor compound pattern SP3 and the fourth two-dimensional semiconductor compound pattern SP4, and an fourth electrode PO4 on the fourth two-dimensional semiconductor compound pattern SP4. In an embodiment, the fourth electrode PO4 may be provided on the fourth fin pattern IFL4. In embodiments of the invention, the first to fourth electrodes PO1 to PO4 may be integrally formed together, and each of which are a part of a gate electrode GE.

Referring to FIG. 5E, the gate electrode GE1 or GE2 may be provided on a top surface, a bottom surface, and side surfaces of each of the first to fourth two-dimensional semiconductor compound patterns SP1, SP2, SP3, and SP4. For example, the transistor according to the present embodiment may be a three-dimensional field effect transistor (e.g., MBCFET (Multi-Bridge Channel Field-Effect Transistor) or GAAFET (Gate-All-Around Field-Effect Transistor)) in which the gate electrode GEL or GE2 is provided to three-dimensionally surround the channel pattern. More specifically, the transistor according to the present embodiment may be a three-dimensional field effect transistor, in which the gate electrode GE1 or GE2 extend to face three surfaces (e.g., top and bottom surfaces and one of side surfaces) of each of the first to fourth two-dimensional semiconductor compound patterns SP1, SP2, SP3, and SP4.

Although not shown, on the first active region AR1, inner spacers may be respectively interposed between the first to third electrodes PO1, PO2, and PO3 of a first gate electrode GE1 and the first source/drain pattern SD1. Each of the first to third electrodes PO1, PO2, and PO3 of the gate electrode GE1 or GE2 may be spaced apart from the first source/drain pattern SD1, with the inner spacer interposed therebetween. The inner spacer may prevent a leakage current issue in the gate electrode GEL or GE2.

Referring back to FIG. 4 and FIGS. 5A to 5E, gate spacers GS may be respectively disposed on opposite side surfaces of the fourth electrode PO4 of the gate electrode GEL or GE2. The gate spacers GS may extend along the gate electrode GEL or GE2 and in the first direction D1. The top surfaces of the gate spacers GS may be coplanar with the top surface of the fourth electrode PO4 of the gate electrode GEL or GE2. In an embodiment, the gate spacers GS may be formed of or include at least one of SiCN, SiCON, and SiN. In another embodiment, the gate spacers GS may be a multi-layered structure, which is formed of or includes at least two different materials selected from SiCN, SiCON, and SiN.

Terms such as “flat,” “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Referring back to FIG. 4 and FIGS. 5A to 5D, a gate capping pattern GP may be provided on the gate electrode GE1 and GE2. The gate capping pattern GP may extend along the gate electrode GE1 and GE2 and in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, and SiN. The gate capping pattern GP may include a first gate capping pattern GP on the gate electrode GE1 and a second gate capping pattern GP on the gate electrode GE2 as described later.

A gate insulating layer GI may be interposed between the gate electrode GEL or GE2 and the plurality of first channel patterns CH1 and between the gate electrode GEL or GE2 and the plurality of second channel patterns CH2. The gate insulating layer GI may cover a top surface, a bottom surface, and opposite side surfaces of each of the first to fourth two-dimensional semiconductor compound patterns SP1, SP2, SP3, and SP4.

In an embodiment, the gate insulating layer GI may include a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In another embodiment, the semiconductor device may include a negative capacitance (NC) FET utilizing a negative capacitance characteristic of the gate insulating layer GI. For example, the gate insulating layer GI may include a ferroelectric layer exhibiting a ferroelectric property, or may include a ferroelectric layer and a paraelectric layer exhibiting a paraelectric property.

The ferroelectric layer may have a negative capacitance, and the paraelectric layer may have a positive capacitance.

In the case where two or more capacitive layers are connected (or stacked) in series and each capacitive layer has a positive capacitance, a total capacitance may be reduced to a value that is less than the capacitance of each of the capacitive layers. By contrast, in the case where at least one of the serially-connected capacitive layers has a negative capacitance, a total capacitance of the serially-connected capacitive layers may have a positive value and may be greater than an absolute value of each capacitance. Accordingly, the transistor's performance and efficiency may be increased. For example, in the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. The dopants may include at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and yttrium (Y).

In the case where the dopants are aluminum (Al), a content of aluminum in the ferroelectric layer may be in a range from 3 to 8 at % (atomic percentage). Here, the content of the dopants (e.g., aluminum atoms) may be a ratio of the number of aluminum atoms to the number of hafnium and aluminum atoms.

In the case where the dopants are silicon (Si), a content of silicon in the ferroelectric layer may be in a range from 2 at % to 10 at %. In the case where the dopants are yttrium (Y), a content of yttrium in the ferroelectric layer may be in a range from 2 at % to 10 at %. In the case where the dopants are gadolinium (Gd), a content of gadolinium in the ferroelectric layer may be in a range from 1 at % to 7 at %. In the case where the dopants are zirconium (Zr), a content of zirconium in the ferroelectric layer may be in a range from 50 at % to 80 at %.

The paraelectric layer may have the paraelectric property. The paraelectric layer may be formed of or include at least one of, for example, silicon oxide and high-k metal oxides. The metal oxides, which can be used as the paraelectric layer, may include at least one of, for example, hafnium oxide, zirconium oxide, and aluminum oxide, but the inventive concept is not limited to these examples.

In an embodiment, the ferroelectric layer and the paraelectric layer may share the same composition, but the atomic arrangements may be different. For example, in the case of hafnium oxide, a crystal structure of the hafnium oxide as a ferroelectric layer may be different from that of the hafnium oxide as a paraelectric layer.

The ferroelectric layer may exhibit the ferroelectric property, only when its thickness is in a specific range. In an embodiment, the ferroelectric layer may have a thickness ranging from 0.5 to 10 nm, but the inventive concept is not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring back to FIGS. 4, 5A to 5E, and 6B, the gate electrode GEL or GE2 may include a first metal pattern and a second metal pattern on the first metal pattern. The first metal pattern may be provided on the gate insulating layer GI and may be adjacent to the first to fourth two-dimensional semiconductor compound patterns SP1, SP2, SP3, and SP4. The first metal pattern may include a work-function metal, which can be used to adjust a threshold voltage of the transistor. By adjusting a thickness and composition of the first metal pattern, it may be possible to realize a transistor having a desired threshold voltage.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta).

In an embodiment, the first to third electrodes PO1, PO2, and PO3 of the gate electrode GE1 or GE2 may be composed of the first metal pattern. The fourth electrode PO4 of the gate electrode GE may include the first metal pattern and the second metal pattern on the first metal pattern.

Referring back to FIGS. 4 and 5C to 5E, the backbone structure (also referred as the isolation wall pattern) DWST may be provided on the first device isolation layer ST1. For example, the backbone structure DWST may be vertically overlapped with the first device isolation layer ST1. The backbone structure DWST may be provided on the substrate 100 and between the first and second active regions AR1 and AR2. In detail, the backbone structure DWST may be provided between the first and second active patterns AP1 and AP2. The backbone structure DWST may extend in the second direction D2. When viewed in a plan view, the backbone structure DWST may be a bar-shaped pattern extending in the second direction D2.

The backbone structure (also referred as the isolation wall pattern) DWST may include a first backbone structure (also referred as a first isolation wall pattern) DWST1 and a second backbone structure (also referred as a second isolation wall pattern) DWST2. Each of the first and second backbone structures DWST1 and DWST2 may be defined as a portion of the backbone structure DWST. The first backbone structure DWST1 may be interposed between the gate electrodes GE1 and GE2. The second backbone structure DWST2 may be interposed between the first and second source/drain patterns SD1 and SD2.

The first backbone structure DWST1 will be described in more detail with reference to FIG. 5E. The first backbone structure DWST1 may be disposed on the first device isolation layer ST1 and may be interposed between the gate electrodes GE1 and GE2. The uppermost surface of the first backbone structure DWST may be located at the same level as the uppermost surface of the gate electrode GEL or GE2 in the third direction D3. For example, the uppermost surface of the first backbone structure DWST1 may be substantially coplanar with the uppermost surface of the gate electrode GEL or GE2.

The first backbone structure DWST1 may include a body portion BDP on the first device isolation layer ST1 and a protruding portion PJP, which extend from the body portion BDP toward the channel seed pattern SDLP. The body portion BDP may be vertically overlapped with the first device isolation layer ST1. The body portion BDP may be placed on side surfaces of the fin patterns IFL to be in contact with the fin patterns IFL. The protruding portion PJP may have a curved surface that is convex toward the channel seed pattern SDLP. The protruding portion PJP may be in contact with the channel seed pattern SDLP.

Unless the context or other statements indicate otherwise, it will be understood that when an element is referred to as “in contact with” another element (or using any form of the word “contact”), there are no intervening elements present at the point of contact. The term “directly” may be used herein to emphasize this meaning. In contrast, when an element is referred to as being “connected” to or “on” another element, it can be directly connected or coupled to or on the other element or intervening elements may be present.

The second backbone structure DWST2 will be described in more detail with reference to FIG. 5D. The second backbone structure DWST2 may be disposed on the first device isolation layer ST1 and may be interposed between the first source/drain pattern SD1 and the second source/drain pattern SD2. The uppermost surface of the second backbone structure DWST2 may be located at a level that is higher than the uppermost surface of each of the first and second source/drain patterns SD1 and SD2 in the third direction D3. The first and second backbone structures DWST1 and DWST2 may include an insulating material. The insulating material may include, for example, silicon oxide, silicon nitride, silicon oxynitride, or combinations thereof.

The first and second backbone structures (also referred as the first isolation wall pattern and the second isolation wall pattern) DWST1 and DWST2 may be formed integrally together, but may have different shapes. For example, the second backbone structure DWST2 may include a body portion BDP′ on the first device isolation layer ST1, but not any protruding portion. The body portions BDP and BDP′ of a backbone structure DWST may have the same widths in the direction D1.

A first interlayer insulating layer 110 may be provided on the substrate 100. The first interlayer insulating layer 110 may cover the gate spacers GS, the first and second source/drain patterns SD1 and SD2, and the second backbone structure DWST2. A top surface of the first interlayer insulating layer 110 may be substantially coplanar with a top surface of the gate capping pattern GP and a top surface of the gate spacer GS. A second interlayer insulating layer 120 may be disposed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an embodiment, each of the first to fourth interlayer insulating layers 110-140 may include a silicon oxide layer.

The single height cell SHC may have a first border BD1 and a second border BD2, which are opposite to each other in the second direction D2. The first and second borders BD1 and BD2 may extend in the first direction D1. The single height cell SHC may have a third border BD3 and a fourth border BD4, which are opposite to each other in the first direction D1. The third and fourth borders BD3 and BD4 may extend in the second direction D2.

Division structures DB, which are opposite to each other in the second direction D2, may be provided at both sides of the single height cell SHC. For example, the division structures DB may be respectively provided on the first and second borders BD1 and BD2 of the single height cell SHC. The division structure DB may extend in the first direction D1 and parallel to the gate electrode GE1 or GE2. A pitch between the division structure DB and the gate electrode GE1 or GE2, which are adjacent to each other, may be substantially equal to the first pitch.

The division structure DB may be provided to penetrate the first interlayer insulating layer 110 and may extend into the first and second active pattern AP1 or AP2. The division structure DB may be inserted into an upper portion of each of the first and second active patterns AP1 and AP2. In an embodiment, the division structure DB may electrically separate an active region of the single height cell SHC from an active region of a neighboring cell. The division structure DB may electrically isolate the gate electrode GE and the two-dimensional semiconductor compound patterns SP1, SP2 and SP3 of a single height cell SHC from those of an adjacent single height cell.

Active contacts AC may be provided to penetrate the first and second interlayer insulating layers 110 and 120 and to be electrically connected to the first and second source/drain patterns SD1 and SD2, respectively. The active contacts AC may be respectively provided at both sides of the gate electrode GEL or GE2. When viewed in a plan view, the active contact AC may be a bar-shaped pattern that extends in the first direction D1.

The active contact AC may be a self-aligned contact. For example, the active contact AC may be formed by a self-alignment process using the gate capping pattern GP and the gate spacer GS. For example, the active contact AC may cover at least a portion of a side surface of the gate spacer GS. Although not shown, the active contact AC may cover a portion of the top surface of the gate capping pattern GP.

A metal-semiconductor compound layer SC (e.g., a silicide layer) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, and cobalt silicide.

Gate contacts GC may be provided to penetrate the second interlayer insulating layer 120 and the gate capping pattern GP and may be electrically connected to the gate electrodes GE, respectively. For example, each gate contacts GC may be electrically connected to at least one of the gate electrodes GE. When viewed in a plan view, the gate contacts GC may be respectively overlapped with the first and second active regions AR1 and AR2. As an example, the gate contact GC may be provided on the second active pattern AP2 (e.g., see FIG. 5B).

In an embodiment, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. For example, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring therebetween.

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CON), and platinum nitride (PtN).

A first metal layer M1 may be provided in the third interlayer insulating layer 130. For example, the first metal layer M1 may include a first power line M1_R1, a second power line M1_R2, and first interconnection lines M1_I. The interconnection lines M1_R1, M1_R2, and M1_I of the first metal layer M1 may extend in the second direction D2 and to be parallel to each other.

In detail, the first and second power lines M1_R1 and M1_R2 may be respectively provided on the third and fourth borders BD3 and BD4 of the single height cell SHC. The first power line M1_R1 may extend along the third border BD3 and in the second direction D2. The second power line M1_R2 may extend along the fourth border BD4 and in the second direction D2.

The first interconnection lines M1_I of the first metal layer M1 may be disposed between the first and second power lines M1_R1 and M1_R2. The first interconnection lines M1_I of the first metal layer M1 may be arranged at a second pitch in the first direction D1. The second pitch may be smaller than the first pitch. A linewidth of each of the first interconnection lines M1_I may be smaller than a linewidth of each of the first and second power lines M1_R1 and M1_R2.

The first metal layer M1 may further include first vias VI1. The first vias VI1 may be provided below the interconnection lines M1_R1, M1_R2, and M1_I, respectively, of the first metal layer M1. The active contact AC and the interconnection line of the first metal layer M1 may be electrically connected to each other through the first via VI1. The gate contact GC and the interconnection line of the first metal layer M1 may be electrically connected to each other through the first via VI1.

The interconnection line of the first metal layer M1 and the first via VI1 thereunder may be formed by separate processes. For example, the interconnection line and the first via VI1 of the first metal layer M1 may be independently formed by respective single damascene processes. The semiconductor device according to the present embodiment may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that extends in the first direction D1. For example, the second interconnection lines M2_I may extend in the first direction D1 and parallel to each other.

The second metal layer M2 may further include second vias VI2, which are respectively provided below the second interconnection lines M2_I. The interconnection line of the first metal layer M1 and the interconnection line of the second metal layer M2 may be electrically connected to each other through the second via VI2. The interconnection line of the second metal layer M2 and the second via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

FIG. 6A is an enlarged sectional view illustrating a portion ‘M’ of FIG. 5A, and FIG. 6B is an enlarged sectional view illustrating a portion ‘N’ of FIG. 5E. For concise description, an element previously described with reference to FIG. 4 and FIGS. 5A to 5E may be identified by the same reference number without repeating an overlapping description thereof.

Referring to FIG. 6A, the fin patterns IFL, the channel supporting patterns CSL, the second two-dimensional semiconductor compound pattern SP2, and the second electrode PO2 of the first gate electrode GE1 may be interposed between the first source/drain patterns SD1. The gate insulating layer GI may be interposed between the second electrode PO2 and the second two-dimensional semiconductor compound pattern SP2 and between the second electrode PO2 and the first source/drain pattern SD1. The gate insulating layer GI may be provided to enclose the second electrode PO2, when viewed in cross-section.

The gate insulating layer GI may include at least one of silicon oxide, silicon oxynitride, and high-k dielectric materials. For example, the gate insulating layer GI may be formed of or include a high-k dielectric material whose dielectric constant is higher than that of silicon oxide. The channel supporting pattern CSL and the gate insulating layer GI may include different high-k dielectric materials from each other. In an embodiment, the channel supporting pattern CSL and the gate insulating layer GI may include the same high-k dielectric material. For example, the channel supporting pattern CSL and the gate insulating layer GI may include hafnium oxide.

Referring to FIG. 6B, the fin patterns IFL may be provided on the second active pattern AP2. The fin patterns IFL may include the first fin pattern IFL1, the second fin pattern IFL2, the third fin pattern IFL3, and the fourth fin pattern IFL4, which are vertically spaced apart from each other. The channel supporting pattern CSL may be provided on the top surface of the first fin pattern IFL1. The channel supporting pattern CSL may be provided on bottom and top surfaces of each of the second and third fin patterns IFL2 and IFL3. The channel supporting pattern CSL may be provided on the bottom surface of the fourth fin pattern IFL4.

The plurality of second channel patterns CH2 (or first channel patterns CH1) may include the first to fourth two-dimensional semiconductor compound patterns SP1, SP2, SP3, and SP4, which are provided on the channel supporting patterns CSL, respectively. The channel seed patterns SDLP1, SDLP2, and SDLP3 may be provided between the plurality of second channel patterns CH2 and the protruding portion PJP of the first backbone structure DWST1. The channel seed patterns may include the first channel seed pattern SDLP1 between the first and second fin patterns IFL1 and IFL2, the second channel seed pattern SDLP2 between the second and third fin patterns IFL2 and IFL3, and the third channel seed pattern SDLP3 between the third and fourth fin patterns IFL3 and IFLA.

In detail, the first two-dimensional semiconductor compound pattern SP1 may extend along the channel supporting pattern CSL from the first channel seed pattern SDLP1 to an opposite side surface of the first fin pattern IFL1. The opposite side surface of the fin pattern may refer to a side surface adjacent to the fourth border BD4. Similarly, the second to fourth two-dimensional semiconductor compound pattern SP2, SP3 and SP4 may extend from a corresponding one (or two) of the channel seed patterns to a corresponding one (or two) of opposite side surface of the fin patterns. The first to fourth two-dimensional semiconductor compound pattern SP1, SP2, SP3 and SP4 may extend from corner areas to the opposite side surfaces. The corner areas are located between channel seed patterns and the channel supporting patterns CSL.

The fourth two-dimensional semiconductor compound pattern SP4 may further extend along a top surface of the fourth fin pattern IFLA. Each of the second and third two-dimensional semiconductor compound patterns SP2 and SP3 may extend from the opposite side surface to the channel seed patterns. Accordingly, each of the second to fourth two-dimensional semiconductor compound patterns SP2, SP3 and SP4 may have a U shape, when viewed in cross-section.

In an embodiment of the invention, an additional channel supporting pattern CSL may be formed on the top surface of the fourth fin pattern IFL4.

The second gate electrode GE2 may be provided on the first to fourth two-dimensional semiconductor compound patterns SP1, SP2, SP3, and SP4. The second gate electrode GE2 may include the first to third electrodes PO1, PO2, and PO3 and the fourth electrode PO4. The first electrode PO1 may be interposed between the first two-dimensional semiconductor compound pattern SP1 and the second two-dimensional semiconductor compound pattern SP2, and the second electrode PO2 may be interposed between the second two-dimensional semiconductor compound pattern SP2 and the third two-dimensional semiconductor compound pattern SP3. The third electrode PO3 may be interposed between the third two-dimensional semiconductor compound pattern SP3 and the fourth two-dimensional semiconductor compound pattern SP4, and the fourth electrode PO4 may be provided on the fourth two-dimensional semiconductor compound pattern SP4.

A gate insulating layer may be interposed between the second gate electrode GE2 and the plurality of second channel patterns CH2. The gate insulating layer may include a first gate insulating layer GI1 on the first two-dimensional semiconductor compound pattern SP1, a second gate insulating layer GI2 on the second two-dimensional semiconductor compound pattern SP2, a third gate insulating layer GI3 on the third two-dimensional semiconductor compound pattern SP3, and a fourth gate insulating layer GI4 on the fourth two-dimensional semiconductor compound pattern SP4. In an embodiment of the invention, though not shown in the drawings, the first to fourth gate insulating layers may be integrally formed together, and each of which are a part of a gate insulating layer. In this case, the gate insulating layer may interpose between the channel seed pattern SDLP and the gate electrode GE.

The first backbone structure DWST1 may be provided on side portions of the first to fourth fin patterns IFL1 to IFL4 and on side portions of the first to third channel seed patterns SDLP1 to SDLP3. The first backbone structure DWST1 may include the body portion BDP and the protruding portions PJP, which laterally extends from the body portion BDP toward the first to third channel seed patterns SDLP1 to SDLP3.

Each of the first to third channel seed patterns SDLP1 to SDLP3 may include a first side surface SS1 and a second side surface SS2, which are opposite to each other in the first direction D1. The first side surface SS1 may be in contact with the protruding portion PJP of the first backbone structure DWST1 and may be a curved surface. The second side surface SS2 may be in contact with the second gate electrode GE2, the gate insulating layer GI, and the plurality of second channel patterns CH2 and may be a flat side surface parallel to the third direction D3. In detail, the second side surface SS2 may be in contact with the electrodes PO1 to PO3, the gate insulating layers GI1 to GI3, the fourth gate insulating layer GI4, and the first to fourth two-dimensional semiconductor compound patterns SP1 to SP4.

The body portion BDP of the first backbone structure DWST1 may be provided on side surfaces of the fin patterns IFL1 to IFL4. The two-dimensional semiconductor compound patterns SP1 to SP4, the gate insulating layers GI1 to GI4, and the gate electrodes GE2 may be sequentially provided on the opposite side surface of the fin pattern IFL1 to IFL4. The channel supporting patterns CSL, the two-dimensional semiconductor compound patterns SP1 to SP4, the gate insulating layers GI1 to GI2, and the gate electrodes GE2 may be sequentially provided on a bottom or top surface of the fin pattern IFL1 to IFL4.

FIG. 6C is an enlarged sectional view illustrating a portion ‘NN’ of FIG. 6B. Referring to FIG. 6C, In an embodiment of the invention, two separated channel seed patterns SDLP may be within a space between two adjacent sacrificial layers SAL. Each of the channel seed patterns SDLP may be at a corner region between the protruding portions PDJ and the channel supporting patterns CSL. In detail, a channel seed pattern SDLP11 may be in a position between the protruding portion PJP, the first two-dimensional semiconductor compound pattern SP1 and channel supporting pattern CSL. Channel seed patterns SDLP12 and SDLP21 may be in positions between the protruding portion, the second two-dimensional semiconductor compound pattern SP2 and channel supporting pattern CSL. A channel seed pattern SDLP22 may be in a position between the protruding portion PJP, the third two-dimensional semiconductor compound pattern SP3 and channel supporting pattern CSL.

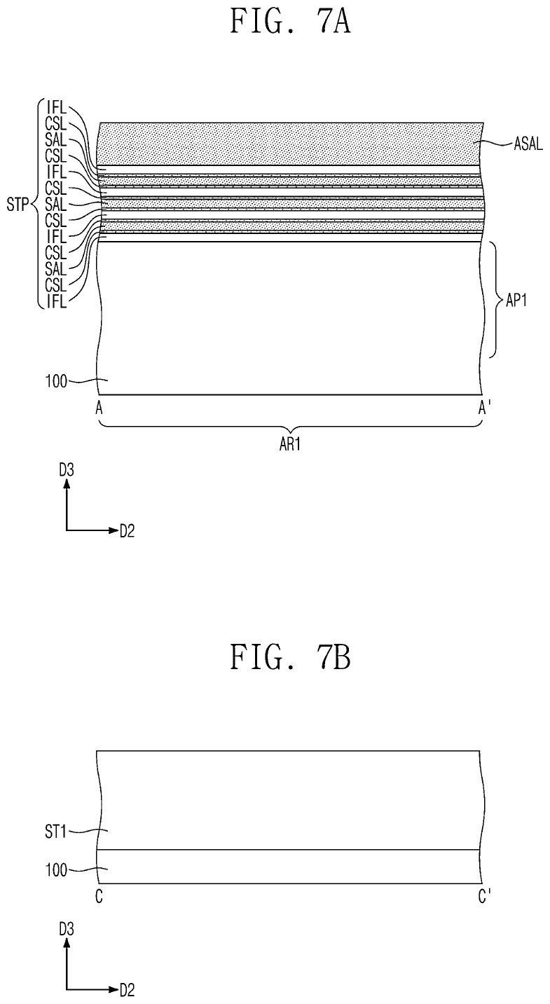

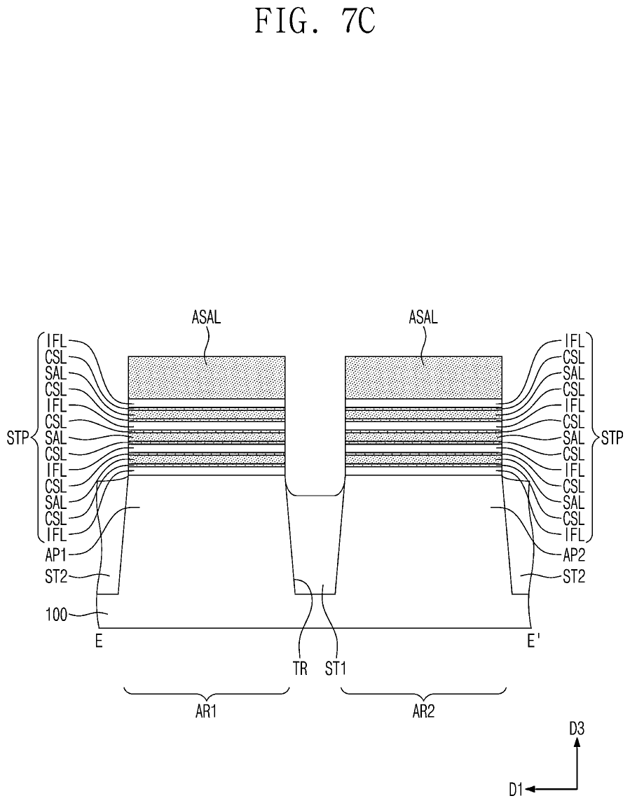

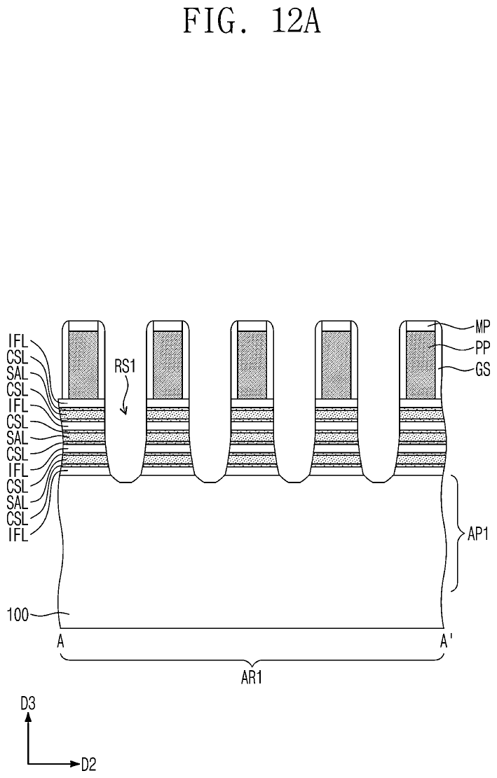

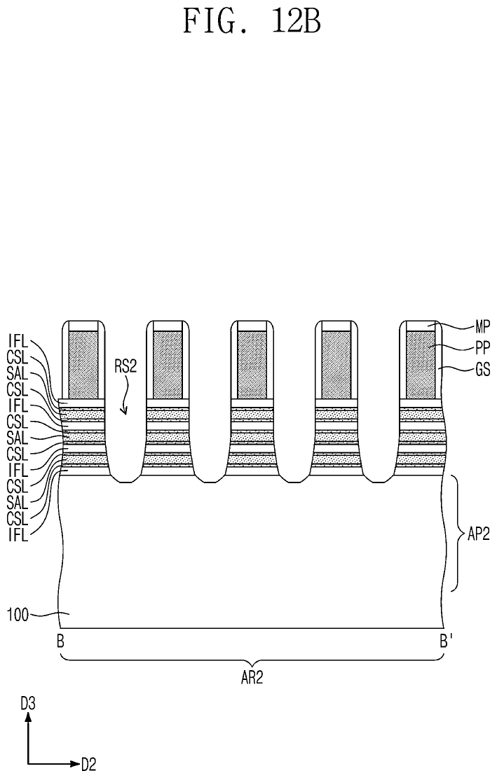

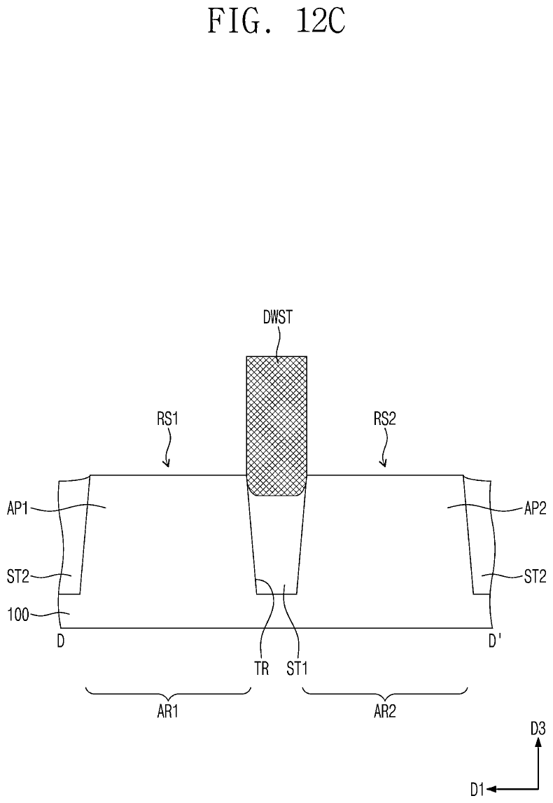

FIGS. 7A to 16D are sectional views illustrating a method of fabricating a semiconductor device according to an embodiment of the inventive concept. In detail, FIGS. 7A, 8A, 9A, 10A, 11A, 12A, 13A, 14A, 15A, and 16A are sectional views taken along a line A-A′ of FIG. 4. FIGS. 12B, 13B, 14B, and 16B are sectional views taken along a line B-B′ of FIG. 4. FIGS. 7B, 9B, 10B, 11B, and 14C are sectional views taken along a line C-C′ of FIG. 4. FIGS. 12C, 13C, 14D, and 16C are sectional views taken along a line D-D′ of FIG. 4. FIGS. 7C, 8B, 9C, 10C, 11C, 14E, 15B, and 16D are sectional views taken along a line E-E′ of FIG. 4.

Referring to FIGS. 7A to 7C, the substrate 100 including the first and second active regions AR1 and AR2 may be provided. The substrate 100 may be a semiconductor substrate that is formed of or includes silicon, germanium, silicon germanium, a compound semiconductor material, or the like. As an example, the substrate 100 may be a silicon substrate. Plurality of insulating fin layers and a plurality of composition layers, each of which includes two sacrificial layers SAL and a channel supporting layer, may be formed on the substrate 100. Each of the plurality of composition layers may be formed to intervene two adjacent ones of the insulating fin layers. Each of the insulating fin layer, the channel supporting layer, the sacrificial layer SAL, and the channel supporting layer may be formed by a deposition process. The deposition process may be a chemical vapor deposition (CVD) process, a physical vapor deposition (PVD) process, or an atomic layer deposition (ALD) process.

The insulating fin layers may include one of silicon oxide, silicon nitride, and silicon oxynitride and may include, for example, silicon oxide (SiOx). The channel supporting layers may include hafnium oxide (HfO2), and in an embodiment, the channel supporting layers may include amorphous hafnium oxide. The sacrificial layers SAL may be formed of or include at least one of silicon (Si), germanium (Ge), and silicon-germanium (SiGe).

An additional sacrificial layer may be formed on the uppermost one of the insulating fin layers. The additional sacrificial layer may be a preliminary sacrificial layer, which is used to form the channel seed pattern SDLP in a subsequent step. A thickness of the additional sacrificial layer in the third direction D3 may be larger than a thickness of each of the sacrificial layers SAL in the third direction D3. The additional sacrificial layer may be formed of a material, which is chosen from the group consisting of silicon (Si), germanium (Ge), and silicon-germanium (SiGe). The additional sacrificial layer may be formed of a material that is different from the material of the sacrificial layer SAL. In an embodiment, the additional sacrificial layer may be formed of or include the same material as the sacrificial layers SAL.

The sacrificial layer SAL and the additional sacrificial layer may include a material having an etch selectivity with respect to the insulating fin layer and the channel supporting layer. For example, the sacrificial layers SAL and the additional sacrificial layer may be formed of or include silicon-germanium (SiGe). A germanium concentration of each of the sacrificial layers SAL and the additional sacrificial layer may be in a range from 10 at % to 30 at %. The germanium concentration of the sacrificial layers SAL may be higher than the germanium concentration of the additional sacrificial layer.

Primary mask patterns may be formed on the additional sacrificial layer. The primary mask patterns may be formed on the first and second active regions AR1 and AR2, respectively, of the substrate 100. The primary mask patterns may be line- or bar-shaped patterns that extend in the second direction D2.

A patterning process using the mask patterns as an etch mask may be performed to form the trench TR defining the first and second active patterns AP1 and AP2. The first active pattern AP1 may be formed on the first active region AR1. The second active pattern AP2 may be formed on the second active region AR2.

A stacking pattern STP may also be formed on each of the first and second active patterns AP1 and AP2 during the patterning process. The stacking pattern STP may include the fin patterns IFL, the channel supporting patterns CSL, the sacrificial layers SAL, and the channel supporting patterns CSL which are repeatedly stacked. Additional sacrificial patterns ASAL may also be formed on the stacking pattern STP along with the first and second active patterns AP1 and AP2, during the patterning process.

The first and second device isolation layers ST1 and ST2 may be formed to fill the trench TR. In detail, an insulating layer may be formed on the substrate 100 to cover the first and second active patterns AP1 and AP2, the stacking patterns STP, and the additional sacrificial patterns ASAL. The first and second device isolation layers ST1 and ST2 may be formed by recessing the insulating layer (i.e., partially removing the insulating layer from the upper surface thereof) to expose the additional sacrificial layer and further to expose sidewalls of the stacking patterns STP, thereby leaving a remaining portion of the insulating layer in the trenches TR.

Referring to FIGS. 7B and 7C, the first device isolation layer ST1 may be formed to fill the trench TR between the first and second active patterns AP1 and AP2. The second device isolation layer ST2 may be formed to fill a trench on the third and fourth borders BD3 and BD4 of FIG. 4. A top surface of the first device isolation layer ST1 may be located at a level that is lower than a top surface of the second device isolation layer ST2 in the third direction D3.

The first and second device isolation layers ST1 and ST2 may be formed of or include an insulating material (e.g., silicon oxide). The stacking patterns STP and the additional sacrificial patterns ASAL may expose a region at which the first and second device isolation layers ST1 and ST2 are located. The first and second active patterns AP1 and AP2 may be formed to vertically (i.e. in the third direction D3) protrude in the first and second active regions AR1 and AR2. The stacking patterns STP and the additional sacrificial patterns ASAL may be formed on the first and second active patterns AP1 and AP2

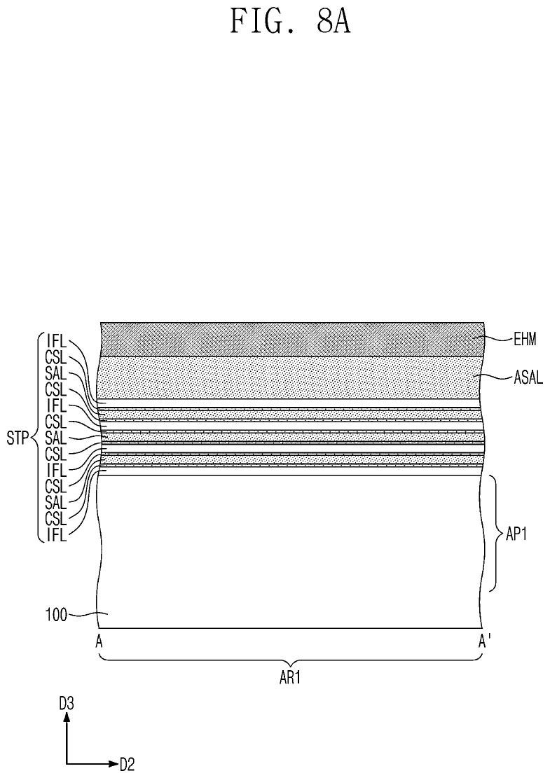

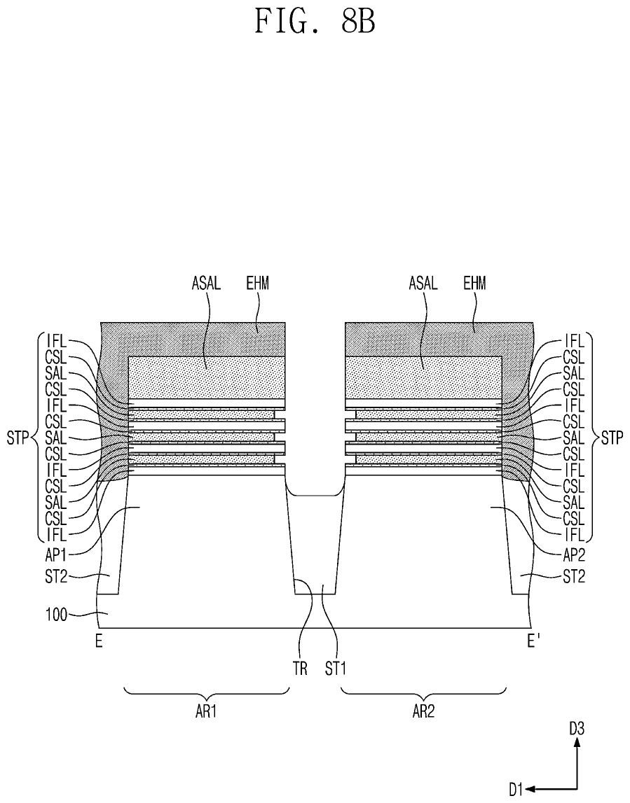

Referring to FIGS. 8A and 8B, first hard mask patterns EHM may be formed on the first and second active regions AR1 and AR2, respectively, of the substrate 100. The first hard mask pattern EHM may be a line-shaped pattern extending in the second direction D2 in a plan view. The first hard mask pattern EHM may have an open region between the first and second active regions AR1 and AR2. The open region may be formed to expose at least a portion of the first device isolation layer ST1.

A patterning process using the first hard mask patterns EHM as an etch mask may be performed to remove a portion of the sacrificial layers SAL, and to form indented or recessed regions on the side surfaces of the stacking patterns STP. The indented regions may be recessed regions, which are formed by partially removing the sacrificial layers SAL in the first direction D1. The patterning process may be an etch-back process or an etching process. The first hard mask patterns EHM may be removed by performing an ashing process or a strip process after the patterning process.

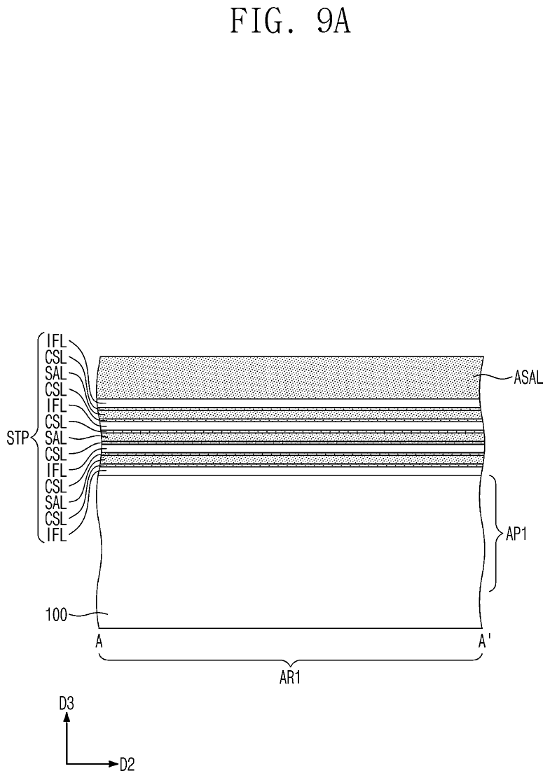

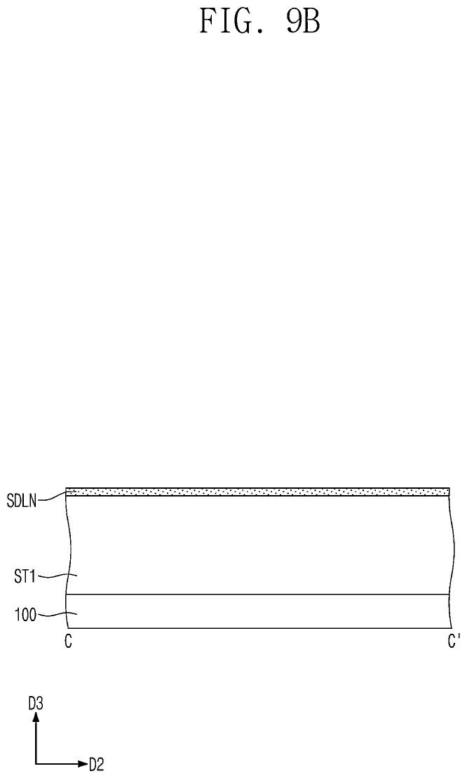

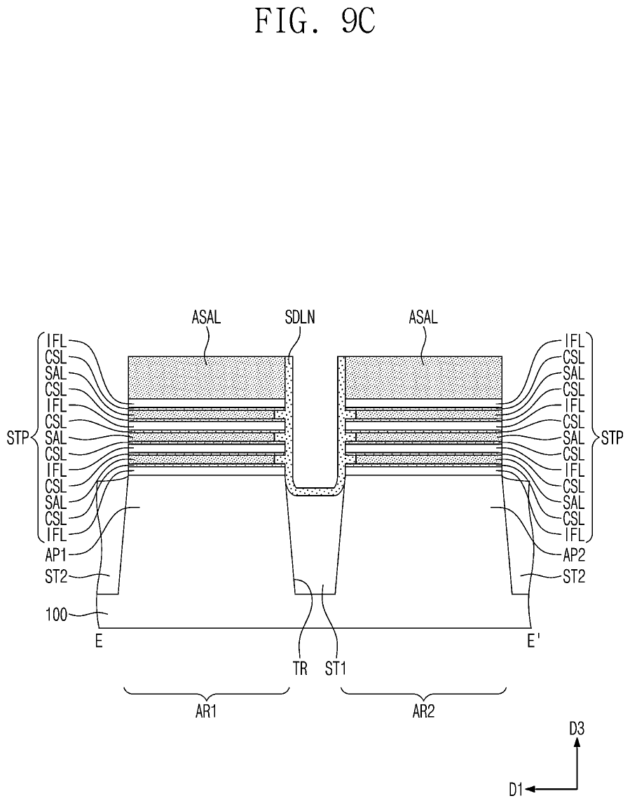

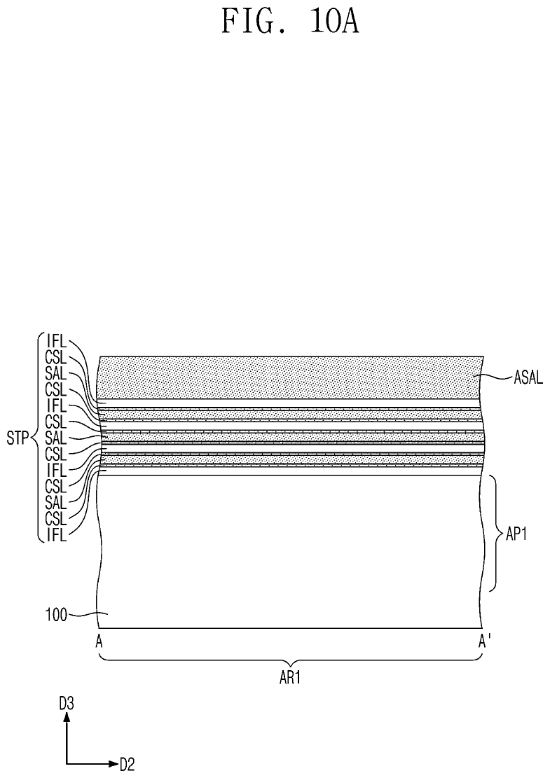

Referring to FIGS. 9A to 9C, a channel seed liner SDLN may be formed to fill a portion of a space between the first and second active patterns AP1 and AP2 and the indented regions. In detail, a transition metal oxide layer may be formed to cover the first device isolation layer ST1, the stacking patterns STP, and the additional sacrificial patterns ASAL. In detail, a transition metal oxide layer may be formed in a recessed region between the two adjacent additional sacrificial patterns ASAL, and may be formed on the sacrificial patterns ASAL. The transition metal oxide layer may be partially removed to expose the additional sacrificial patterns ASAL by performing an etching process, thereby leaving a portion of the transition metal oxide layer in the recessed region. The remaining portion of the transition metal oxide layer may be the channel seed liner SDLN.

The etching process may be a dry etching process. In embodiments of the invention, a portion of the transition metal oxide on the second device isolation layer ST2 may also be removed by the etching process or by an additional removing process. In an embodiment, the transition metal oxide layer may be formed of or include at least one of WOx and MoOx.

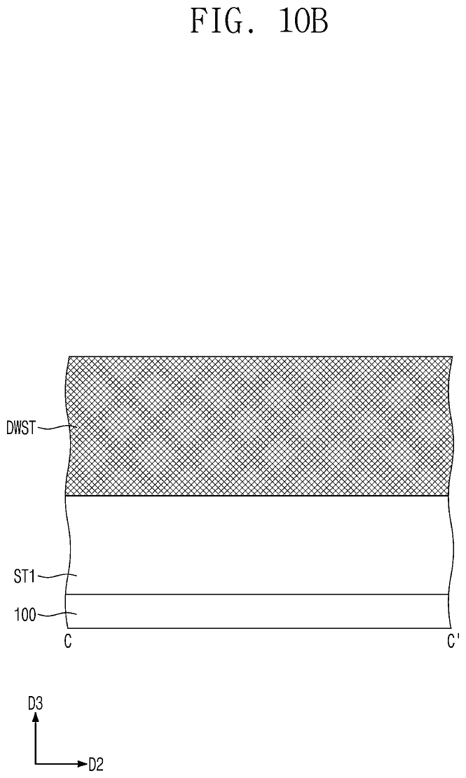

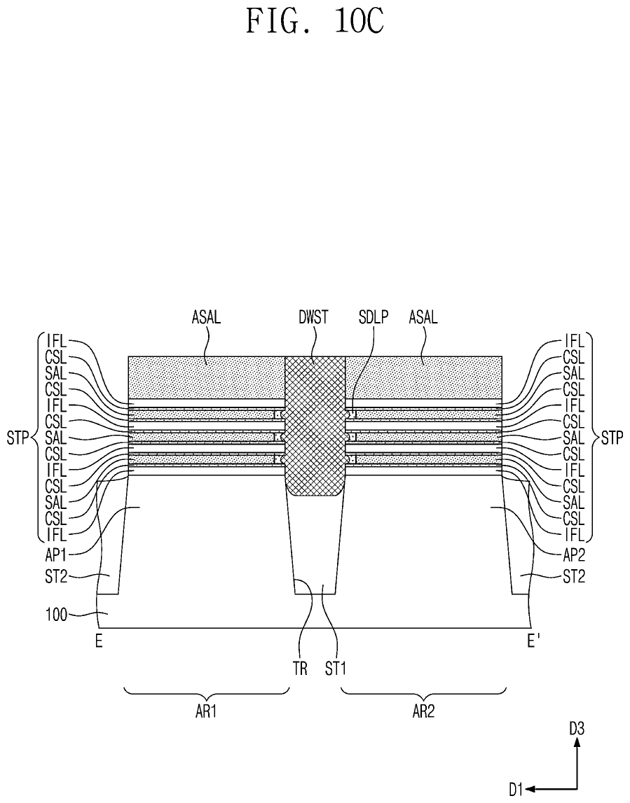

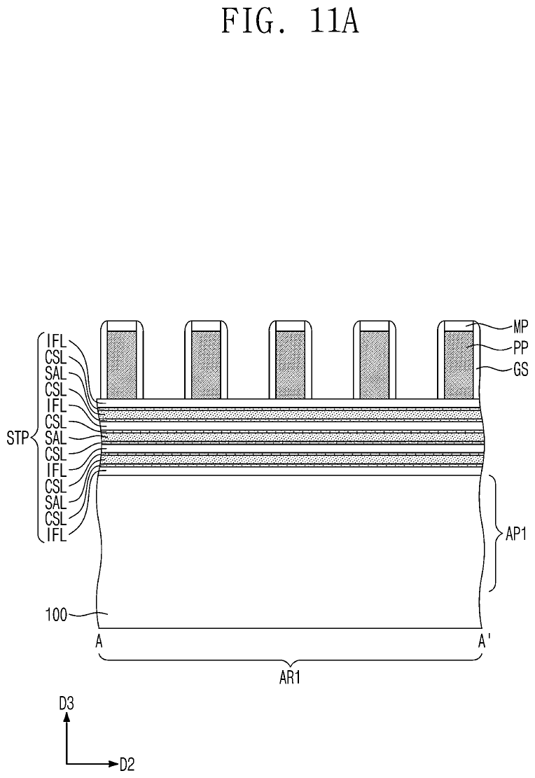

Referring to FIGS. 10A to 10C, the channel seed patterns SDLP may be formed by performing an etching process on the channel seed liner SDLN. The etching process may be a dry etching process or a wet etching process and may be performed to expose the top surface of the first device isolation layer ST1 and side surfaces of the fin patterns IFL and the channel supporting patterns CSL. The channel seed liner SDLN may be recessed (or partially removed) in the first direction D1 to remain a portion of the channel seed liner SDLN, which corresponds to the channel seed patterns SDLP. The other portion of the channel seed liner SDLN is removed as shown in the drawings. The channel seed patterns SDLP are respectively interposed between the channel supporting patterns CSL. Inner sidewall of the channel seed patterns SDLP may have a concavely curved surface. The inner sidewall may correspond to the first side surface SS1 of FIG. 6B.

In an embodiment of the invention, by controlling the removed amount of the channel seed liner SDLN, two separated channel seed patterns SDLP may be formed within a space between two adjacent sacrificial layers SAL as shown in FIG. 6C. In this case, the removed amount of the channel seed liner SDLN may be increased compared to the embodiment of FIGS. 10A to 10C. For example, the inner sidewalls of the channel seed patterns SDLP in FIGS. 10A to 10C may be further removed by an etchant in the etching process of the step described in FIGS. 10A to 10C. Accordingly, the channel seed patterns SDLP may be confined to a corner region of the indented regions formed in the step described in FIGS. 8A and 8B.

In an embodiment of the invention, a formation process of the channel seed patterns SDLP in the first active region AR1 may be performed independently (i.e., not by the same process) from a formation process of the channel seed patterns SDLP in the second active region AR2. The shape or size channel seed patterns SDLP in the first active region AR1 may be different from those in the second active region AR2. This process scheme of separately forming may be helpful to adjust electrical performance of NMOSFET and PMOSFET in the single height cell. For example, by utilizing the difference of the shape or size, the channel patterns CH1 and CH2 may be formed such that the thickness of the channel pattern CH1 may be different from that of the channel pattern CH2, thereby adjusting the driving current of the NMOSFET and PMOSFET independently to each other.

The backbone structure DWST may be formed between the stacking patterns STP. In detail, a backbone layer may be formed on the first and second device isolation layers ST1 and ST2, the stacking patterns STP, and the additional sacrificial patterns ASAL. The backbone layer may cover top surfaces of the first and second device isolation layers ST1 and ST2, side surfaces of the stacking patterns STP, and side and top surfaces of the additional sacrificial patterns ASAL. The backbone layer may be formed to have a uniform thickness. The backbone layer may be formed by performing a chemical vapor deposition (CVD) process, a physical vapor deposition (PVD) process, or an atomic layer deposition (ALD) process.

The backbone layer may include an insulating material. In an embodiment, the backbone layer may be formed of or include at least one of silicon oxide, silicon nitride, and silicon oxynitride.

The backbone layer may be planarized to expose the top surfaces of the additional sacrificial patterns ASAL. The planarization of the backbone layer may be performed using a chemical mechanical polishing (CMP) process. A slurry, which can remove silicon oxide or silicon nitride at a higher removal rate compared with silicon-germanium (SiGe), may be used in the CMP process. In an embodiment, the planarization process may be performed to remove the backbone layers on the additional sacrificial patterns ASAL. As a result, the backbone structure DWST may be formed between the stacking patterns STP.

In detail, the backbone structure DWST may be formed on the first device isolation layer ST1 and between the stacking patterns STP. The backbone structure DWST may be formed to cover a side surface of one of the additional sacrificial patterns ASAL, a side surface of one of the stacking patterns STP, a top surface of the first device isolation layer ST1, a side surface of another of the stacking patterns STP, and a side surface of another of the additional sacrificial patterns ASAL and then may be formed to fill a space between the stacking patterns STP. A top surface of the backbone structure DWST may be substantially coplanar with a top surface of each of the additional sacrificial patterns ASAL. The backbone structure DWST may include the body portion BDP (e.g., see FIG. 5E), which is provided on the first device isolation layer ST1, and the protruding portion PJP (e.g., see FIG. 5E), which laterally extend from the body portion BDP toward the channel seed pattern SDLP.

An additional mask pattern may be formed on the additional sacrificial patterns ASAL and the backbone structure DWST. The additional mask pattern may be a line- or bar-shaped pattern extending in the first direction D1 in a plan view. The additional mask pattern may expose the second device isolation layer ST2

An etching process using the mask pattern as an etch mask may be performed to remove the backbone layer, which is left on the second device isolation layer ST2, after the planarization process. The etching process may be an anisotropic dry etching process. Since the backbone layer and the second device isolation layer ST2 may include silicon oxide, an upper portion of the second device isolation layer ST2 may be slightly removed during the etching process. The top surface of the second device isolation layer ST2 may be located at a level, which is higher than or equal to the top surface of the first device isolation layer ST1 in the third direction D3.

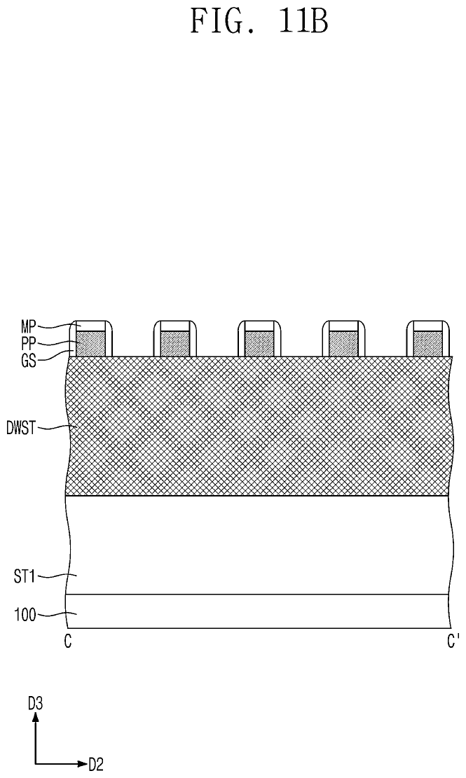

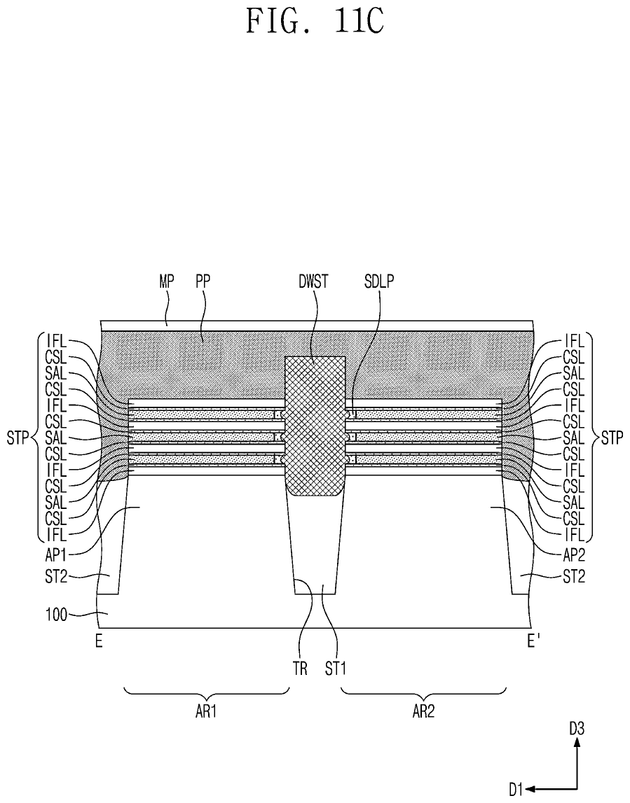

Referring to FIGS. 11A to 11C, the additional sacrificial patterns ASAL may be selectively removed to leave only the stacking pattern STP on each of the first and second active patterns AP1 and AP2. In detail, a selective etching process may be performed to leave the stacking patterns STP and the backbone structure DWST and remove only the additional sacrificial patterns ASAL. An etch recipe for the etching process may be chosen to have a higher etch rate with respect to a layer (e.g., a silicon germanium layer) having a relatively high germanium concentration. For example, the etching process may be chosen to have a higher etch rate with respect to a first silicon germanium layer than a second silicon germanium layer, and the germanium concentration difference between the first and second silicon germanium layer is 10 at % or more.

Since only the additional sacrificial patterns ASAL are selectively removed, the top surface of the backbone structure DWST may be located at a level, which is higher than a top surface of each of the stacking patterns STP in the third direction D3.

Sacrificial patterns PP may be formed on the substrate 100 to cross the stacking patterns STP and the backbone structure DWST. Each of the sacrificial patterns PP may be a line- or bar-shaped pattern that extends in the first direction D1 in a plan view. The sacrificial patterns PP may be repeatedly arranged at a first pitch in the second direction D2.

In detail, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

The gate spacers GS may be formed on opposite side surfaces of each of the sacrificial patterns PP. The gate spacers GS may be formed by a conformal deposition of a gate spacer layer on the substrate 100 and anisotropically etching of the gate spacer layer. In an embodiment, the gate spacer GS may be a multi-layered structure including at least two layers.

Referring to FIGS. 12A to 12C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the second device isolation layer ST2 may be further recessed at both sides of each of the first and second active patterns AP1 and AP2.

In detail, the first recesses RS1 may be formed by etching the stacking pattern STP on the first active pattern AP1 using the hard mask patterns MP and the gate spacers GS as an etch mask. The first recess RS1 may be formed in a region between the sacrificial patterns PP.

The first recess RS1 may be formed in a region between two adjacent sacrificial patterns PP. A width of the first recess RS1 in the second direction D2 may decrease as it goes downward to the substrate 100. For example, The first recess RS1 may taper down and narrow sharply at the bottom portion thereof. The second recesses RS2 in the stacking pattern STP on the second active pattern AP2 may be formed by substantially the same method as or similar method to the method to form the first recesses RS1, and may have substantially the same shape as or a similar shape to that of the first recesses RS1.

Referring to FIG. 12C, on the first and second active patterns AP1 and AP2, and on the first device isolation layer ST1, the stacking patterns STP may be partially removed to form the first and second recesses RS1 and RS2 exposing most of the backbone structure DWST. In detail, most of a side surface of the backbone structure DWST may be exposed to the outside (or to the first and second recesses RS1 and RS2). During the partially removing process, the gate spacers GS, the sacrificial patterns PP and the hard mask patterns MP may be utilized as etch masks.

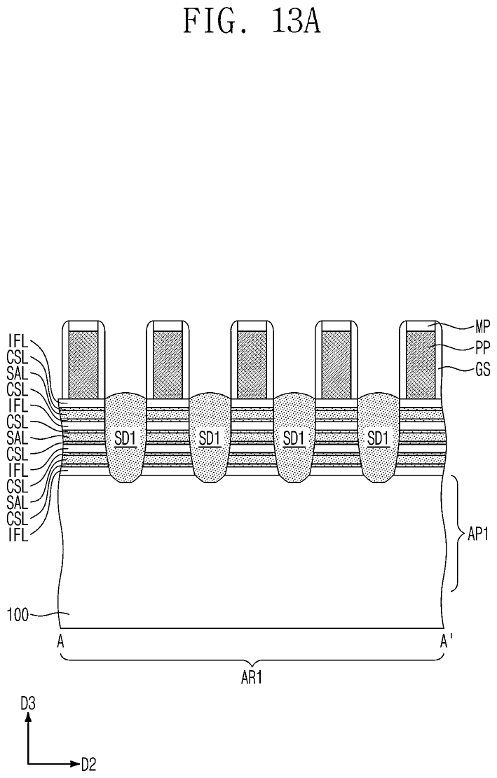

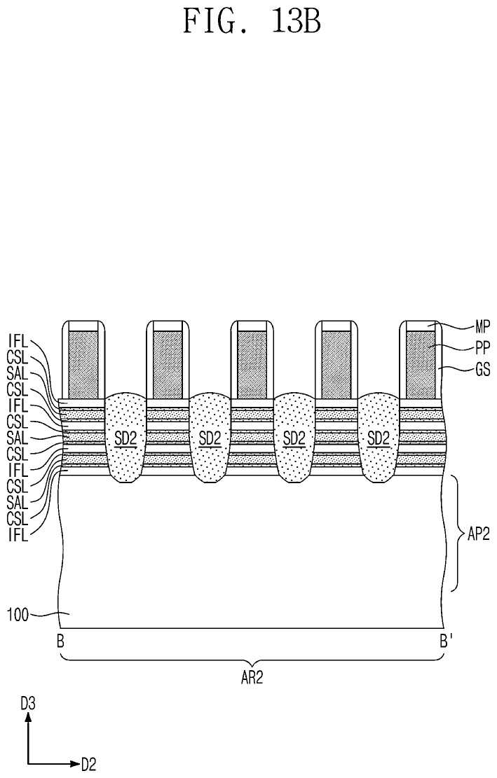

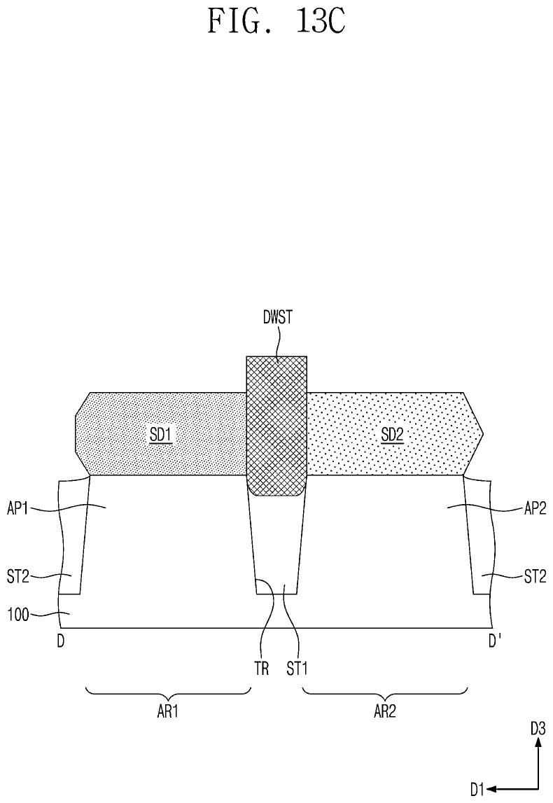

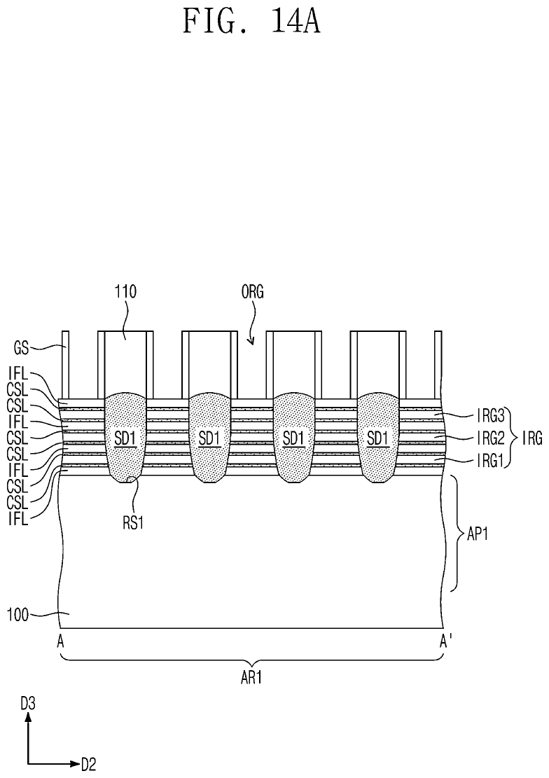

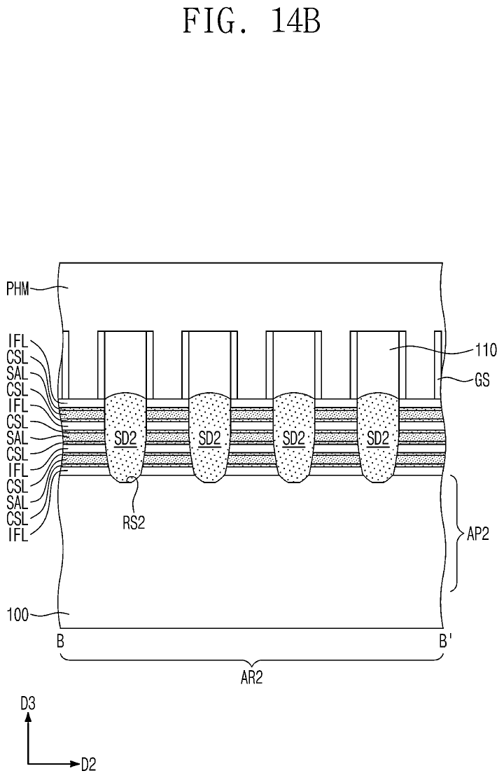

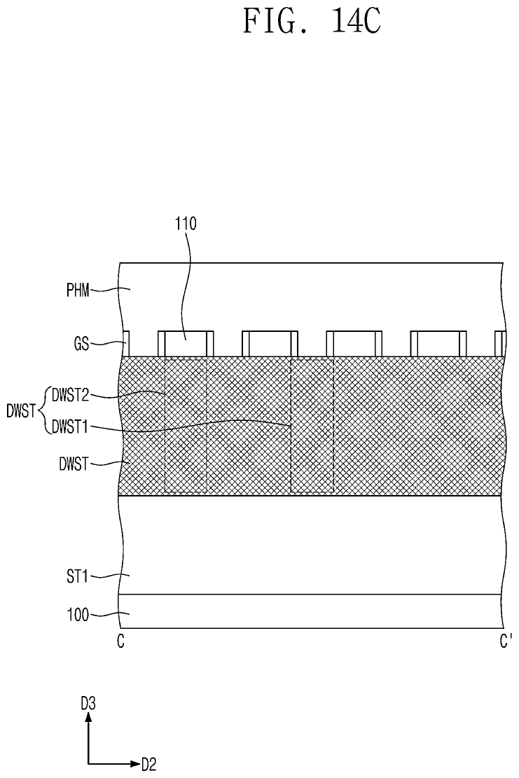

Referring to FIGS. 13A to 13C, the first source/drain patterns SD1 may be formed in the first recesses RS1, respectively. In detail, a SEG (selective epitaxial growth) process, in which an inner surface of the first recess RS1 is used as a seed layer, may be performed to form an epitaxial layer filling the first recess RS1. The epitaxial layer may be grown using the sacrificial layers SAL, which are exposed by the first recess RS1, as a seed layer. In an embodiment, the SEG process may include a chemical vapor deposition (CVD) process or a molecular beam epitaxy (MBE) process.

In an embodiment, the first source/drain pattern SD1 may be formed of or include the same semiconductor material (e.g., Si) as the substrate 100. During the formation of the first source/drain pattern SD1, the first source/drain pattern SD1 may be doped in-situ with n-type impurities (e.g., phosphorus, arsenic, or antimony). Alternatively, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a SEG process, in which an inner surface of the second recess RS2 is used as a seed layer.

In an embodiment, the second source/drain pattern SD2 may be formed of or include a semiconductor material (e.g., SiGe) whose lattice constant is greater than that of a semiconductor material of the substrate 100. During the formation of the second source/drain pattern SD2, the second source/drain pattern SD2 may be doped in-situ with p-type impurities (e.g., boron, gallium, or indium). Alternatively, impurities may be injected into the second source/drain pattern SD2, after the formation of the second source/drain pattern SD2.

In an embodiment, the kind of impurities in the first and second source/drain patterns SD1 and SD2 may vary depending on whether each of the first and second active regions AR1 and AR2 is an NMOSFET or PMOSFET region. In the case where the first and second active regions AR1 and AR2 are NMOSFET regions, the first and second source/drain patterns SD1 and SD2 may be doped in-situ with n-type impurities (e.g., phosphorus, arsenic, or antimony)). In the case where the first and second active regions AR1 and AR2 are PMOSFET regions, the first and second source/drain patterns SD1 and SD2 may be doped in-situ with p-type impurities (e.g., boron, gallium, or indium). In embodiments of the invention, the first active region AR1 may be NMOSFET region, the second active region AR2 may be PMOSFET region (or vice versa). In this case, the first and second source/drain patterns SD1 and SD2 may be formed using patterned masks and different epitaxial processes.

Referring to FIG. 13C, a side surface of each of the first and second source/drain patterns SD1 and SD2 may be in contact with the backbone structure DWST. The top surface of each of the first and second source/drain patterns SD1 and SD2 may be located at a level that is lower than the top surface of the backbone structure DWST in the third direction D3.

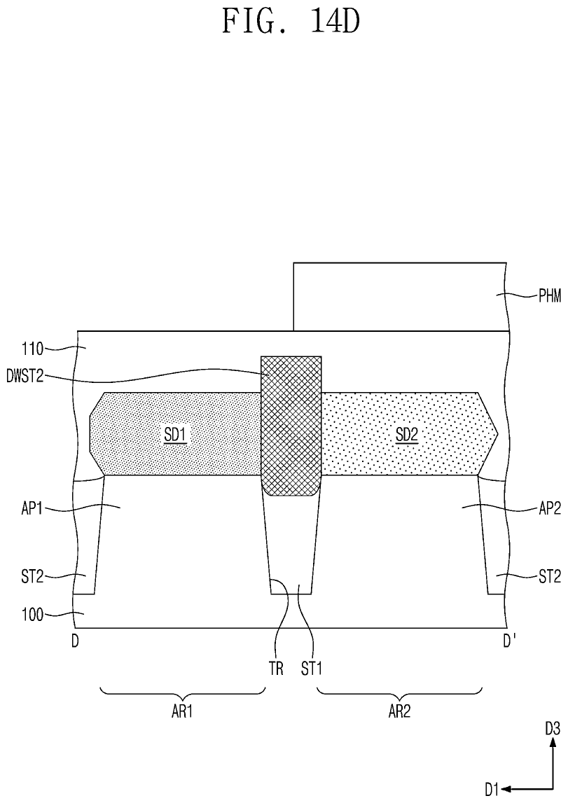

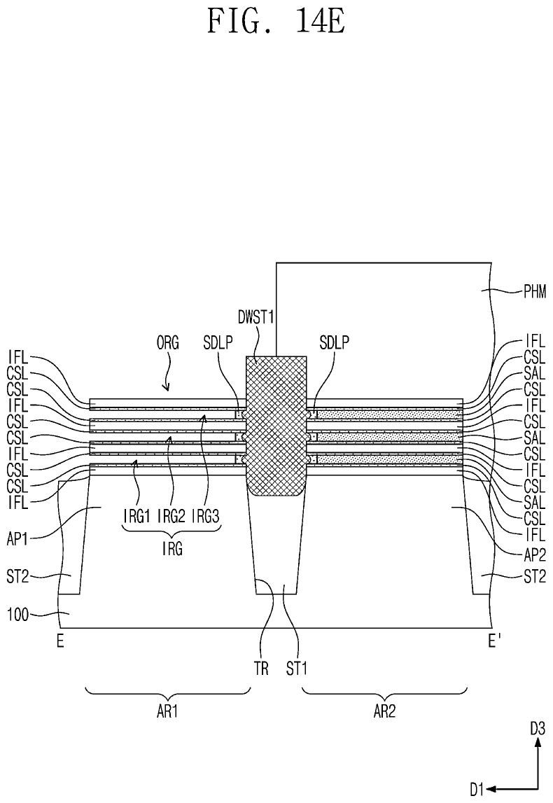

Referring to FIGS. 14A to 14E, the first interlayer insulating layer 110 may be formed to cover the first and second source/drain patterns SD1 and SD2, the hard mask patterns MP, and the gate spacers GS. In an embodiment, the first interlayer insulating layer 110 may include a silicon oxide layer. The first interlayer insulating layer 110 may cover the first and second source/drain patterns SD1 and SD2 and the second backbone structure DWST2.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the hard mask patterns MP may be removed during the planarization process. Accordingly, the first interlayer insulating layer 110 may have a top surface that is coplanar with the top surfaces of the sacrificial patterns PP and the top surfaces of the gate spacers GS.

In an embodiment, the exposed sacrificial patterns PP may be selectively removed. Since the sacrificial patterns PP are removed, an outer region ORG may be formed to expose the fin patterns IFL (e.g., see FIG. 14E). The removal of the sacrificial patterns PP may include a wet etching process which is performed using an etching solution capable of selectively etching polysilicon.

A second hard mask pattern PHM may be formed on the second active region AR2 of the substrate 100. The second hard mask pattern PHM may be a line-shaped pattern extending in the second direction D2. The second hard mask pattern PHM may be formed to extend to a region on the first device isolation layer ST1 between the first and second active regions AR1 and AR2. Here, the second hard mask pattern PHM may cover the outer region ORG on the second active region AR2.

The sacrificial layers SAL, which are exposed through the outer region ORG on the first active region AR1, may be selectively removed to form inner regions IRG (e.g., see FIG. 14E). In detail, a selective etching process may be performed to leave the fin patterns IFL, the channel supporting patterns CSL, and the channel seed patterns SDLP and to remove only the sacrificial layers SAL. An etch recipe for the etching process may be chosen to have a higher etch rate with respect to a layer (e.g., a silicon germanium layer) having a relatively high germanium concentration. For example, the etching process may be chosen to have a higher etch rate with respect to a first silicon germanium layer than a second silicon germanium layer, and the germanium concentration difference between the first and second silicon germanium layer is 10 at % or more.

The sacrificial layers SAL on the first active region AR1 may be removed during the etching process. The etching process may be a wet etching process. An etchant material, which is used in the etching process, may be chosen to quickly remove the sacrificial layer SAL having a relatively high germanium concentration.

Referring back to FIG. 14E, since the sacrificial layers SAL are selectively removed, the fin patterns IFL, the channel supporting patterns CSL, and the channel seed patterns SDLP may be left on the first active pattern AP1. Empty regions, which are formed by removing the sacrificial layers SAL, may be first to third inner regions IRG1, IRG2, and IRG3, respectively. In detail, a first inner region IRG1 may be formed between the first fin pattern IFL1 of FIG. 6B and the second fin pattern IFL2 of FIG. 6B, a second inner region IRG2 may be formed between the second fin pattern IFL2 of FIG. 6B and the third fin pattern IFL3 of FIG. 6B, and a third inner region IRG3 may be formed between the third fin pattern IFL3 of FIG. 6B and the fourth fin pattern IFL4 of FIG. 6B.

Referring back to FIGS. 14C to 14E, the backbone structure DWST may include the first backbone structure DWST1 and the second backbone structure DWST2. Each of the first and second backbone structures DWST1 and DWST2 may be defined as a portion of the backbone structure DWST. In embodiments of the invention, the first and second backbone structures DWST1 and DWST2 may be formed integrally, and may be part of the backbone structure DWST. The first backbone structure DWST1 may be interposed between the fin patterns IFL on the first active region AR1 and the fin patterns IFL on the second active region AR2. The first backbone structure DWST1 may also be interposed between the channel seed patterns SDLP on the first active region AR1 and the channel seed patterns SDLP on the second active region AR2. The second backbone structure DWST2 may be interposed between the first and second source/drain patterns SD1 and SD2.

According to an embodiment of the inventive concept, since the backbone structure DWST is formed between the NMOSFET and PMOSFET regions, a distance between the transistors on the different regions may be reduced, and this may make it possible to reduce an occupying area of each of unit cells, which constitute the semiconductor device, in a substrate. For example, it may be possible to increase the number of unit cells which are formed on the substrate. Thus, the integration density of the semiconductor device may be increased.

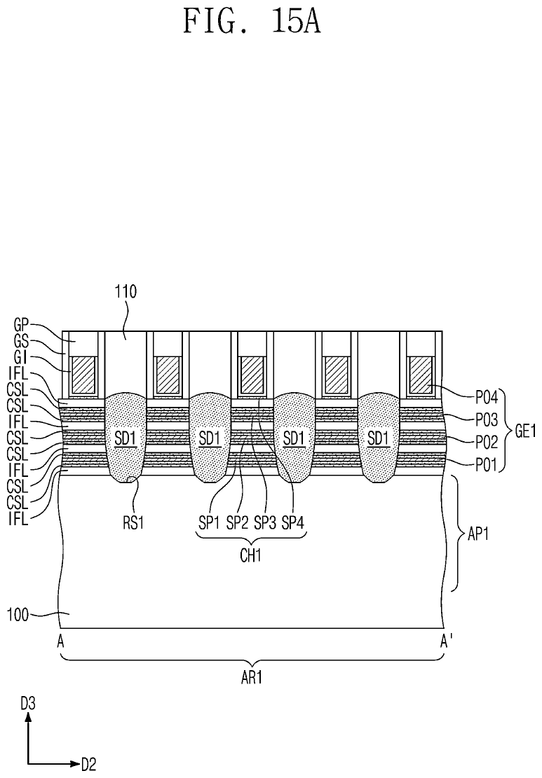

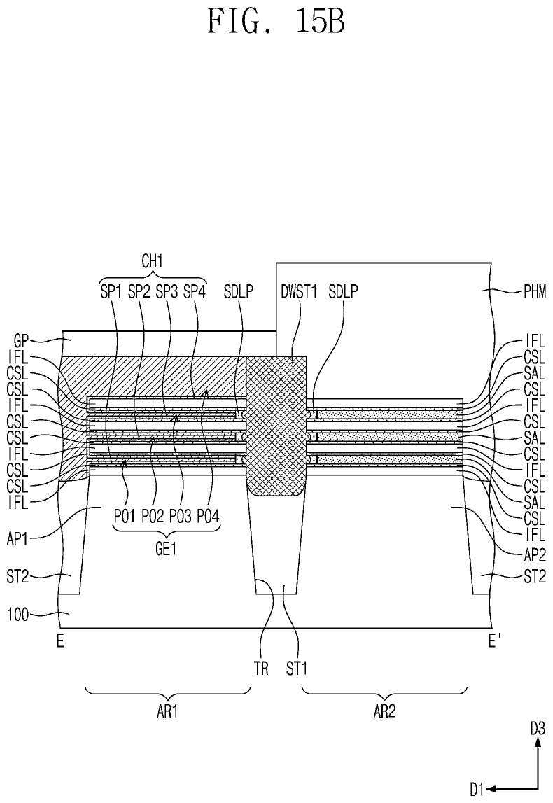

Referring to FIGS. 15A and 15B, the first to fourth two-dimensional semiconductor compound patterns SP1, SP2, SP3, and SP4, which are grown from the channel seed patterns SDLP, may be formed on the channel supporting patterns CSL that are adjacent to the channel seed patterns SDLP. The first to fourth two-dimensional semiconductor compound patterns SP1, SP2, SP3, and SP4 may constitute the plurality of first channel pattern CH1.

In detail, the first and second two-dimensional semiconductor compound patterns SP1 and SP2 may be laterally grown from the first channel seed pattern SDLP1 of FIG. 6B and may be formed on the channel supporting patterns CSL adjacent to the first channel seed pattern SDLP1. The first two-dimensional semiconductor compound pattern SP1, which is grown on the channel supporting pattern CSL, may extend to a side surface of the first fin pattern IFL1 of FIG. 6B. The second two-dimensional semiconductor compound pattern SP2, which is grown on the channel supporting pattern CSL, may extend to a side surface of the second fin pattern IFL2 of FIG. 6B.

The second and third two-dimensional semiconductor compound patterns SP2 and SP3 may be laterally grown from the second channel seed pattern SDLP2 of FIG. 6B and may be formed on the channel supporting patterns CSL adjacent to the second channel seed pattern SDLP2. The second two-dimensional semiconductor compound pattern SP2, which is grown on the channel supporting pattern CSL, may extend to a side surface of the second fin pattern IFL2 of FIG. 6B and may be connected to the second two-dimensional semiconductor compound pattern SP2, which extends from the first channel seed pattern SDLP1. The third two-dimensional semiconductor compound pattern SP3, which is grown on the channel supporting pattern CSL, may extend to a side surface of the third fin pattern IFL3 of FIG. 6B.

The third and fourth two-dimensional semiconductor compound patterns SP3 and SP4 may be laterally grown from the third channel seed pattern SDLP3 of FIG. 6B and may be formed on the channel supporting patterns CSL adjacent to the third channel seed pattern SDLP3. The third two-dimensional semiconductor compound pattern SP3, which is grown on the channel supporting pattern CSL, may extend to a side surface of the third fin pattern IFL3 of FIG. 6B and may be connected to the third two-dimensional semiconductor compound pattern SP3, which extends from the second channel seed pattern SDLP2. The fourth two-dimensional semiconductor compound pattern SP4, which is grown on the channel supporting pattern CSL, may extend to a side surface of the fourth fin pattern IFL4 of FIG. 6B. Furthermore, the fourth two-dimensional semiconductor compound pattern SP4 may or may not extend to a top surface of the fourth fin pattern IFL4.

In an embodiment of the invention, an additional channel supporting pattern CSL may be formed on the top surface of the fourth fin pattern IFL4 to facilitate the forming (i.e., growth) of the fourth two-dimensional semiconductor compound pattern SP4 on the top surface of the fourth fin pattern IFL4.

Each of the first to fourth two-dimensional semiconductor compound patterns SP1, SP2, SP3, and SP4 may be formed of two-dimensional transition metal chalcogenide material by performing a CVD process. For example, in the case where each of the first to fourth two-dimensional semiconductor compound patterns SP1, SP2, SP3, and SP4 is formed of MoS2, Mo(CO)6 (g), MoCl5 (g), or MoOCl4 (g) may be used as a source material of Mo, and H2S (g) may be used as a source material of S. The source materials may be changed depending on the kind of the two-dimensional transition metal chalcogenide materials, which are included in the first to fourth two-dimensional semiconductor compound patterns SP1, SP2, SP3, and SP4, but the inventive concept is not limited to this example. In embodiments of the invention, the material of the first to fourth two-dimensional semiconductor compound patterns may be grown in the form of a single-crystalline structure. In an embodiment of the invention, the two-dimensional semiconductor compound patterns CH1 (or CH2) may be formed to cover the second side surface SS2 (e.g., see FIG. 6B) such that, the two-dimensional semiconductor compound pattern CH1 (or CH2) may interpose between the channel seed pattern SDLP and the gate electrode GE.

According to an embodiment of the inventive concept, the material of the channel supporting patterns CSL may be formed of amorphous hafnium oxide as a base pattern, before forming the channel pattern CH1 or CH2. The two-dimensional transition metal chalcogenide is more readily and uniformly formed on a hafnium oxide layer (i.e., channel supporting patterns CSL) than on a silicon oxide layer (i.e., fin patterns IFL). Accordingly, For example it may be possible to more easily form the two-dimensional transition metal chalcogenide, which is used as the channel pattern of the semiconductor device. It may be possible to efficiently fabricate the semiconductor device, and consequently to improve the reliability of the semiconductor device.

The gate insulating layers GI1, GI2, GI3, and GI4 of FIG. 6B may be formed on the first to fourth two-dimensional semiconductor compound patterns SP1, SP2, SP3, and SP4. Each of the gate insulating layers GI1, GI2, GI3, and GI4 of FIG. 6B may be formed to enclose a corresponding one of the first to fourth two-dimensional semiconductor compound patterns SP1, SP2, SP3, and SP4. For example, each of the gate insulating layers GI1, GI2, GI3, and GI4 of FIG. 6B may be formed on a top surface, a side surface, and a bottom surface of a corresponding one of the first to fourth two-dimensional semiconductor compound patterns SP1, SP2, SP3, and SP4. The gate insulating layers GI1, GI2, and GI3 of FIG. 6B may be formed in the first to third inner regions IRG1, IRG2, and IRG3, respectively. The fourth gate insulating layer GI4 of FIG. 6B may be formed in the outer region ORG.

The first gate electrode GE1 may be formed on the gate insulating layer. In detail, the first gate electrode GE1 may be formed on a high-k dielectric layer. The first gate electrode GE1 may include the first to third electrodes PO1, PO2, and PO3, which are formed in the first to third inner regions IRG1, IRG2, and IRG3, respectively, and the fourth electrode PO4, which is formed in the outer region ORG. A first composite gate layer may be formed, and planarized to have a reduced height, thereby forming the first gate electrode GE1. In an embodiment, a top surface of the first gate electrode GE1 may be coplanar with a top surface of the first backbone structure DWST1. The gate capping pattern GP may be formed on the first gate electrode GE1.

In detail, the formation of the first gate electrode GE1 may include forming the first composite gate layer in the first to third inner regions IRG1, IRG2, and IRG3 and the outer region ORG. The first composite gate layer may include a first metallic layer and a first gate metal layer formed on the first metallic layer. A chemical mechanical polishing (CMP) process may be performed on the first composite gate layer using the first interlayer insulating layer 110 as a stopper. The first metallic layer may include a metal nitride layer, and the first gate metal layer may include a metal material having low resistance.

The formation of the first composite gate layer may include depositing first composite gate layer to cover the gate insulating layer GI, the first interlayer insulating layer 110, and a top surface of the gate spacer GS. The CMP process on first composite gate layer may include removing first composite gate layer using slurry.

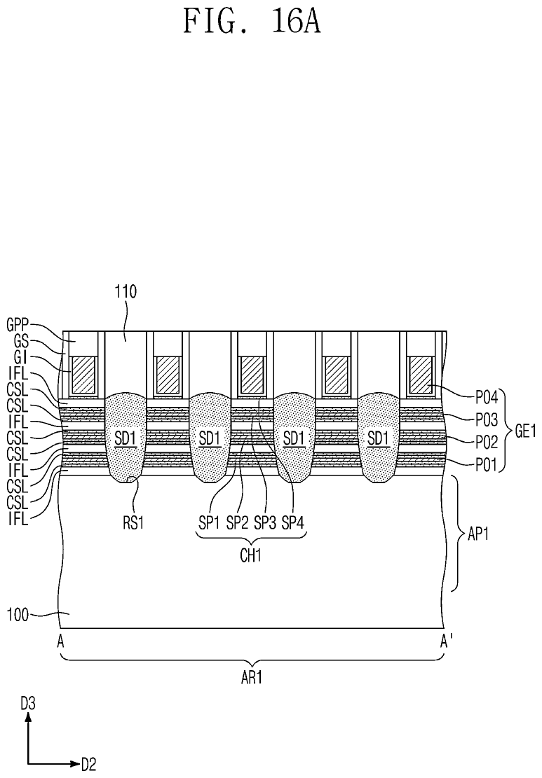

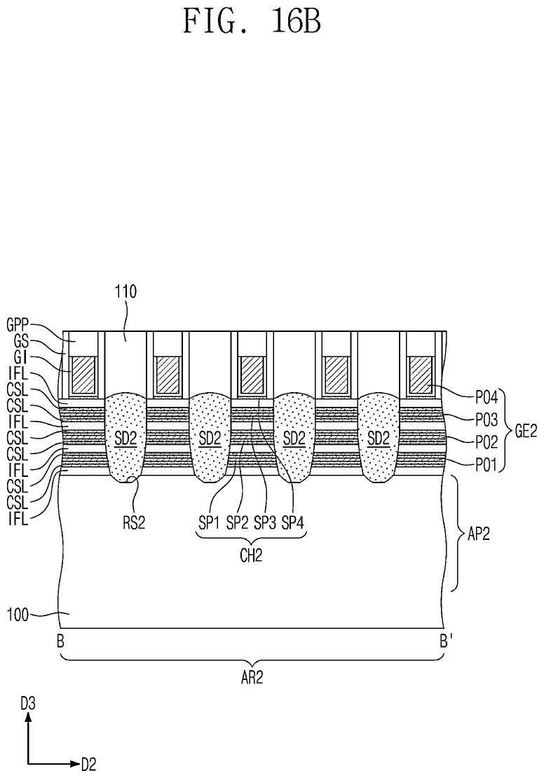

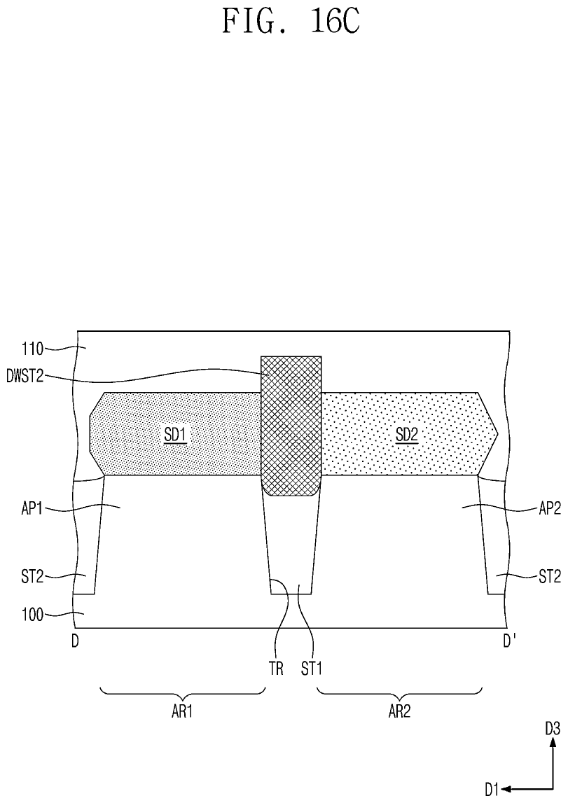

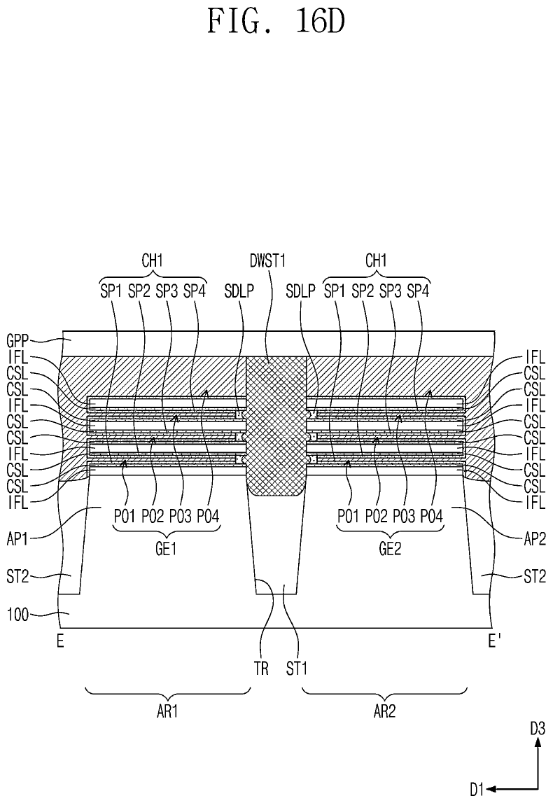

Referring to FIGS. 16A to 16D, an ashing process or a strip process may be performed to remove the second hard mask pattern PHM. A third hard mask pattern (not shown in the drawings) may be formed on the first active region AR1 of the substrate 100. The third hard mask pattern may be a line-shaped pattern extending in the second direction D2. The third hard mask pattern may be formed to extend to a region on the first device isolation layer ST1 between the first and second active regions AR1 and AR2. Thus, the third hard mask pattern may cover the first interlayer insulating layer 110 and the gate capping pattern GP on the first active region AR1. The gate capping pattern GP on the first active region AR1 may be referred to as a first gate capping pattern.

The sacrificial layers SAL, which are exposed through the outer region ORG on the second active region AR2, may be selectively removed to form the inner regions IRG. The inner regions IRG on the second active region AR2 may be formed by substantially the same or similar method as that for the inner regions IRG on the first active region AR1.

The first to fourth two-dimensional semiconductor compound patterns SP1, SP2, SP3, and SP4, which are grown from the channel seed patterns SDLP, may be formed on the channel supporting patterns CSL that are adjacent to the channel seed patterns SDLP. The first to fourth two-dimensional semiconductor compound patterns SP1, SP2, SP3, and SP4 may constitute the plurality of second channel patterns CH2.

The plurality of second channel patterns CH2, the gate insulating layers on the plurality of second channel patterns CH2, and the second gate electrode GE2 on the gate insulating layers may be formed by substantially the same or similar method as that for the plurality of first channel patterns CH1, the gate insulating layers on the plurality of first channel patterns CH1, and the first gate electrode GE1 on the gate insulating layers.

In detail, the second gate electrode GE2 may be formed by forming a second composite gate layer and planarizing the second composite gate layer to have a reduced height. In an embodiment, a top surface of the second gate electrode GE2 may be substantially coplanar with the top surface of the first backbone structure DWST1 and the top surface of the first gate electrode GE1.

An additional gate capping pattern may be formed on the second gate electrode GE2. The additional gate capping pattern may be referred to as a second gate capping pattern. In FIGS. 16A to 16D, for the purpose of simplicity, the additional gate capping pattern and the gate capping pattern GP on the first gate electrode GE1 described above are depicted as a single component GPP. In an embodiment, the additional gate capping pattern and the gate capping pattern GP may be planarized to have coplanar upper surfaces. In an embodiment of the invention, the first and second gate capping patterns may be formed integrally. For example, the gate capping pattern GP (in this case, it may be referred to as preliminary capping pattern) on the first gate electrode GE1 described above may be removed before forming the additional gate capping pattern.

Referring back to FIGS. 5A to 5E, the third hard mask pattern may be removed, and the first interlayer insulating layer 110 is formed on the first and second gate electrode GE1 and GE2. The second interlayer insulating layer 120 may be formed on the first interlayer insulating layer 110. The second interlayer insulating layer 120 may include a silicon oxide layer. The active contacts AC may be formed to penetrate the second interlayer insulating layer 120 and the first interlayer insulating layer 110 and may be electrically connected to the first and second source/drain patterns SD1 and SD2. The gate contact GC may be formed to penetrate the second interlayer insulating layer 120 and the gate capping pattern GP and to be electrically connected to the gate electrode GE.

The formation of each of the active and gate contacts AC and GC may include forming the barrier pattern BM and forming the conductive pattern FM on the barrier pattern BM. The barrier pattern BM may be conformally formed and may include a metal layer and a metal nitride layer. The conductive pattern FM may be formed of or include a low resistance metallic material.

Referring to FIG. 5B, the active contact AC, which is connected to the second source/drain pattern SD2, may include the upper insulating pattern UIP. The upper insulating pattern UIP may prevent a short phenomenon or a coupling phenomenon between the gate contact GC and the active contact AC, which are adjacent to each other. The upper insulating pattern UIP may include an insulating material.

The division structures DB may be respectively formed on the first and second borders BD1 and BD2 of the single height cell SHC. The division structure DB may penetrate the second interlayer insulating layer 120 and the gate electrode GE and may extend into the active pattern AP1 or AP2. The division structure DB may be formed of or include an insulating material (e.g., silicon oxide or silicon nitride). In an embodiment, the division structure DB may include a metallic material.

The third interlayer insulating layer 130 may be formed on the active contacts AC and the gate contacts GC. The first metal layer M1 may be formed in the third interlayer insulating layer 130. The first metal layer M1 may include the first interconnection line M1_I, which is electrically connected to at least one of the active and gate contacts AC and GC. The fourth interlayer insulating layer 140 may be formed on the third interlayer insulating layer 130. The second metal layer M2 may be formed in the fourth interlayer insulating layer 140.

In a three-dimensional field effect transistor according to an embodiment of the inventive concept, a backbone structure may be formed between the NMOSFET and PMOSFET regions to reduce an occupying area of a unit cell, which constitutes a logic device, in a substrate. For example, it may be possible to increase the number of unit cells formed on the substrate and consequently to increase an integration density of the semiconductor device.

In a three-dimensional field effect transistor according to an embodiment of the inventive concept, an amorphous hafnium oxide layer may be formed as a base pattern, before forming a channel pattern, and in this case, it may be possible to easily form a channel pattern containing two-dimensional transition metal chalcogenide. Since the channel pattern is faster formed on a hafnium oxide layer than on a silicon oxide layer, the semiconductor device including the same may be fabricated efficiently. For example, it may be possible to more easily form the two-dimensional transition metal chalcogenide, which is used as the channel pattern of the semiconductor device, and consequently to improve the reliability of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including an active pattern;
a fin pattern on the active pattern;
a first channel supporting pattern on a bottom surface of the fin pattern and a second channel supporting pattern on a top surface of the fin pattern;
a channel pattern on each of the first and second channel supporting patterns;
a gate electrode on the channel pattern;
a channel seed pattern provided on a side surface of the channel pattern; and
an isolation wall pattern on a side surface of the channel seed pattern and a side surface of the fin pattern,
wherein the channel pattern extends from a region on the first channel supporting pattern to a region on the second channel supporting pattern via a side surface of the fin pattern.

2. The semiconductor device of claim 1, wherein the first and second channel supporting patterns have an amorphous structure.

3. The semiconductor device of claim 2, wherein the first and second channel supporting patterns comprise hafnium oxide (HfO₂).

4. The semiconductor device of claim 1, further comprising a device isolation layer defining the active pattern,
wherein the isolation wall pattern comprises:
wherein a body portion on the device isolation layer; and
wherein a protruding portion extends from the body portion toward the channel seed pattern.

5. The semiconductor device of claim 4, wherein the protruding portion has a curved surface that is convex toward the channel seed pattern.

6. The semiconductor device of claim 4, further comprising a gate insulating layer interposed between the gate electrode and the channel pattern,
wherein the channel seed pattern comprises a first side surface and a second side surface,
wherein the first side surface is in contact with the protruding portion, and
wherein the second side surface is in contact with the channel pattern.

7. The semiconductor device of claim 6,
wherein the first side surface has a curved surface, and
wherein the second side surface is a flat surface that is parallel to a direction perpendicular to the substrate.

8. The semiconductor device of claim 6, wherein the gate insulating layer comprises a high-k dielectric material which has a dielectric constant higher than silicon oxide (SiOx).

9. The semiconductor device of claim 8, wherein the high-k dielectric material comprises at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

10. The semiconductor device of claim 6,
wherein the body portion of the isolation wall pattern is placed on a side surface of the fin pattern, and
wherein the channel pattern, the gate insulating layer, and the gate electrode are placed on an opposite side surface of the fin pattern.

11. The semiconductor device of claim 1, wherein a top surface of the gate electrode and a top surface of the isolation wall pattern are coplanar with each other.

12. A semiconductor device, comprising:
a substrate including an active pattern;
a fin pattern on the active pattern;
channel supporting patterns on each of bottom and top surfaces of the fin pattern;
a channel pattern on the channel supporting patterns;
a gate electrode on the channel pattern;
a gate insulating layer interposed between the gate electrode and the channel pattern;
a channel seed pattern provided on a side surface of the channel pattern; and
an isolation wall pattern on a side surface of the channel seed pattern and a side surface of the fin pattern,
wherein the channel seed pattern comprises transition metal oxide, and
wherein the channel pattern comprises two-dimensional transition metal chalcogenide.

13. The semiconductor device of claim 12, wherein the channel seed pattern comprises at least one of WOₓ and MoOₓ.

14. The semiconductor device of claim 12, wherein the channel pattern comprises at least one of MoS₂, WS₂, MoSe₂, WSe₂, MoTe₂, and WTe₂.

15. The semiconductor device of claim 12,
wherein the fin pattern comprises silicon oxide or silicon oxynitride, and
wherein the channel supporting patterns comprises hafnium oxide (HfOₓ).

16. The semiconductor device of claim 15, wherein the channel supporting patterns have an amorphous structure.

17. The semiconductor device of claim 12,
wherein the isolation wall pattern comprise an insulating material, and
wherein the insulating material comprises silicon oxide, silicon nitride, silicon oxynitride or combinations thereof.

18. A semiconductor device, comprising:
a substrate including a first active pattern and a second active pattern;
a device isolation layer defining the first and second active patterns;
first fin patterns on the first active pattern;
second fin patterns on the second active pattern;
first channel supporting patterns on the first fin patterns and on the first active pattern, the first channel supporting patterns being vertically spaced apart from each other;
second channel supporting patterns on the second fin patterns and on the second active pattern, second channel supporting patterns being vertically spaced apart from each other;
first two-dimensional semiconductor compound patterns on the first channel supporting patterns;
second two-dimensional semiconductor compound patterns on the second channel supporting patterns;
a first source/drain pattern connected to the first two-dimensional semiconductor compound patterns;
a second source/drain pattern connected to the second two-dimensional semiconductor compound patterns;
a first gate electrode on the first two-dimensional semiconductor compound patterns, portions of the first gate electrode being interposed between adjacent ones of the first two-dimensional semiconductor compound patterns;
a second gate electrode on second two-dimensional semiconductor compound patterns, portions of the second gate electrode being interposed between adjacent ones of the second two-dimensional semiconductor compound patterns;
an isolation wall pattern on the device isolation layer, the isolation wall pattern comprising a body portion on the device isolation layer and protruding portions protruding from the body portion;
first channel seed patterns interposed between the protruding portions and the first two-dimensional semiconductor compound patterns;
second channel seed patterns interposed between the protruding portions and the second two-dimensional semiconductor compound patterns;
a first gate insulating layer interposed between the first gate electrode and each of the first and second two-dimensional semiconductor compound patterns;
a second gate insulating layer interposed between the second gate electrode and each of the second two-dimensional semiconductor compound patterns;
a gate capping pattern on a top surface of the first and second gate electrodes;
an interlayer insulating layer covering the first and second source/drain patterns and the gate capping pattern;
a gate contact provided to penetrate the gate capping pattern and the interlayer insulating layer and electrically connected to at least one of the first and second gate electrodes;
a first interconnection line electrically connected to the gate contact; and
a second interconnection line electrically connected to the first metal layer,
wherein a first side surface of each of the first and second channel seed patterns is in contact with the protruding portions, and
wherein a second side surface of each of the first and second channel seed patterns is in contact with the first and second two-dimensional semiconductor compound patterns.

19. The semiconductor device of claim 18, wherein a total number of the channel seed patterns is smaller than a total number of the fin patterns.

20. The semiconductor device of claim 18, wherein:
the first and second channel supporting patterns comprise amorphous hafnium oxide,
the first and second channel seed patterns comprise at least one of WOₓ and MoOₓ, and
the first and second two-dimensional semiconductor compound patterns comprise at least one of MoS₂, WS₂, MoSe₂, WSe₂, MoTe₂, and WTe₂.
